(19) United States
(12) Patent Application Publication
(10) Pub. No.: US 2026/0011630 A1
(43) Pub. Date: Jan. 8, 2026

(54) STACKED STRUCTURES FOR SEMICONDUCTOR PACKAGES AND METHODS OF FORMING SAME

(71) Applicant: Taiwan Semiconductor Manufacturing Co., Ltd., Hsinchu (TW)

(72) Inventors: Chuei-Tang Wang, Taichung City (TW); Yen-Ming Chen, Chu-Pei City (TW); Yu-Ming Hsiao, Hsinchu (TW); Shu An Shang, Kaohsiung City (TW); Kam Heng Lee, Hsinchu (TW)

(21) Appl. No.: 18/928,889

(22) Filed: Oct. 28, 2024

Related U.S. Application Data
(60) Provisional application No. 63/667,173, filed on Jul. 3, 2024.

(51) Int. Cl. H01L 23/498; H01L 21/48; H01L 23/00; H01L 23/13; H01L 23/14; H01L 25/18

(52) U.S. Cl. CPC H01L 23/49822; H01L 21/4857; H01L 23/13; H01L 23/142; H01L 23/49833; H01L 23/49838; H01L 24/16; H01L 24/32; H01L 24/73; H01L 25/18; H01L 2224/16227; H01L 2224/32225; H01L 2224/73203; H01L 2924/30101

(57) ABSTRACT

A structure includes a first core substrate; an adhesive layer on the first core substrate; a second core substrate on the adhesive layer, wherein the second core substrate includes a first cavity; a first semiconductor device within the first cavity; a first insulating film extending over the second core substrate, over a top surface of the first semiconductor device, and within the first cavity; a through via extending through the first insulating film, the first core substrate, and the second core substrate; a first routing structure on the first core substrate and electrically connected to the through via; and a second routing structure on the first insulating film and electrically connected to the through via and the first semiconductor device.

### PRIORITY CLAIM AND CROSS-REFERENCE

This application claims the benefit of U.S. Provisional Application No. 63/667,173, filed on Jul. 3, 2024, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 13 illustrate cross-sectional views of intermediate steps during a process for forming a package substrate structure comprising a multi-stack core substrate, in accordance with some embodiments.

FIG. 14 illustrates a cross-sectional view of package comprising a package substrate structure, in accordance with some embodiments.

FIG. 15 illustrates a cross-sectional view of package comprising a package substrate structure, in accordance with some embodiments.

FIGS. 16 through 23 illustrate cross-sectional views of intermediate steps during a process for forming a package substrate structure comprising a multi-stack core substrate, in accordance with some embodiments.

FIGS. 24 through 35 illustrate cross-sectional views of intermediate steps during a process for forming a package substrate structure comprising a multi-stack core substrate, in accordance with some embodiments.

FIGS. 36 through 41 illustrate cross-sectional views of intermediate steps during a process for forming a package substrate structure comprising a multi-stack core substrate, in accordance with some embodiments.

FIGS. 42 through 51 illustrate cross-sectional views of intermediate steps during a process for forming a package substrate structure comprising a multi-stack core substrate, in accordance with some embodiments.

FIGS. 52 through 59 illustrate cross-sectional views of intermediate steps during a process for forming a package substrate structure comprising a multi-stack core substrate, in accordance with some embodiments.

FIGS. 60 through 67 illustrate cross-sectional views of intermediate steps during a process for forming a package substrate structure comprising a multi-stack core substrate, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, package substrate structures formed of stacked structures of core substrates are described. For example, core substrates can be bonded together to form a single multi-stack core substrate. In some embodiments, components (e.g., passive devices, dies, etc.) are embedded within a multi-stack core substrate, which can allow for improved package functionality, flexibility, and performance. The multi-stack core substrates are thicker than single core substrates, which can improve rigidity and package stability.

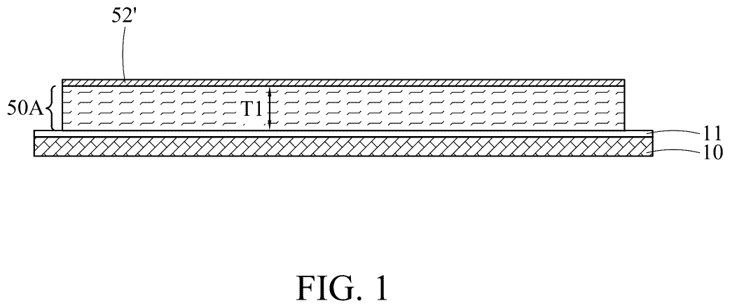

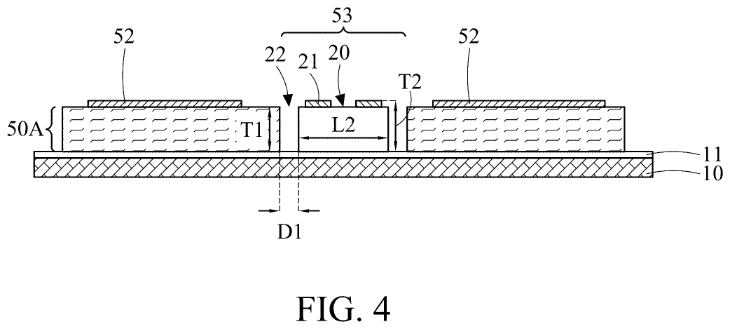

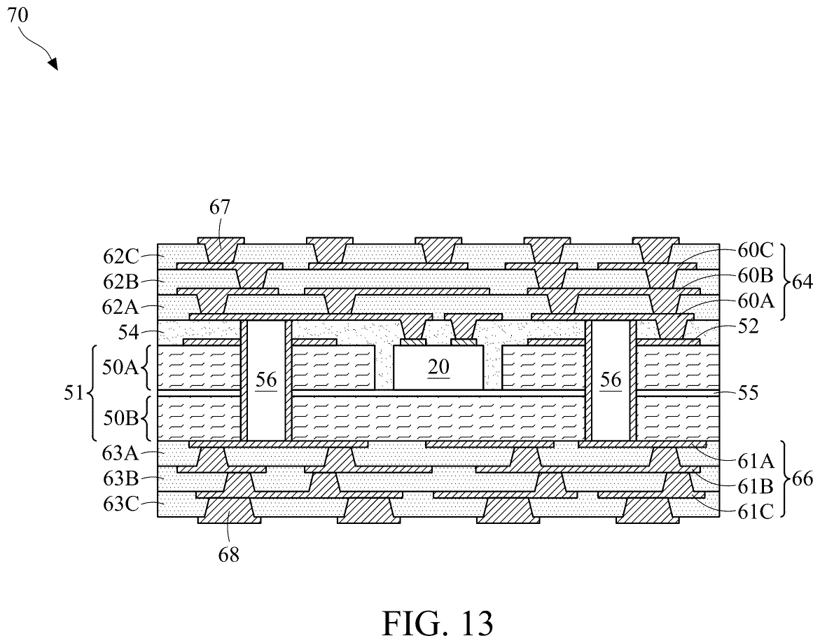

FIGS. 1 through 13 illustrate intermediate steps in the formation of a package substrate structure 70 (see FIG. 13) comprising a multi-stack core substrate, in accordance with some embodiments. FIG. 1 illustrates a cross-sectional view of a first core substrate 50A attached to a first carrier 10, in accordance with some embodiments. In some embodiments, the first core substrate 50A may include a material such as Ajinomoto build-up film (ABF), a pre-impregnated composite fiber (prepreg) material, a resin film, an epoxy, a molding compound, an epoxy molding compound, fiberglass-reinforced resin materials, printed circuit board (PCB) materials, silica filler, polymer materials, polyimide materials, paper, glass fiber, non-woven glass fabric, glass, ceramic, other build-up materials, other laminates, the like, or combinations thereof. Other materials are possible. In some embodiments, the first core substrate 50A may have a thickness T1 that is in the range of about 50 μm to about 650 μm, though other thicknesses are possible. In some cases, the thickness T1 is determined to correspond to a thickness T2 of a component 20, described in greater detail below for FIG. 4.

In some embodiments, a conductive pre-layer 52′ is formed on a top surface of the first core substrate 50A. The conductive pre-layer 52′ may comprise one or more layers of copper, nickel, aluminum, other conductive materials, the like, or a combination thereof that are laminated, deposited, or otherwise formed onto a side of the first core substrate 50A. In some cases, the conductive pre-layer 52′ may comprise a metal foil, such as a copper foil or the like. In this manner, in some cases, the first core substrate 50A may be a copper-clad laminate (CCL) substrate or the like. Other materials or types of conductive layers are possible.

The first carrier 10 may be a glass carrier substrate, a ceramic carrier substrate, a tape, or the like. The first carrier 10 may be a wafer or the like, such that multiple structures can be formed on the first carrier 10 simultaneously. In some cases, the first core substrate 50A is attached to the first carrier 10 using a release layer 11. The release layer 11 may be an adhesive material or the like, which may be removed along with the first carrier 10 from the overlying structures that will be formed in subsequent steps. For example, the release layer 11 may be formed of a polymer-based material. In some embodiments, the release layer 11 is an epoxy-based thermal-release material, which loses its adhesive property when heated, such as a light-to-heat-conversion (LTHC) release coating. In other embodiments, the release layer 11 may be an ultra-violet (UV) glue, which loses its adhesive property when exposed to UV lights. The release layer 11 may be dispensed as a liquid and cured, may be a laminate film laminated onto the first carrier 10, or may be the like. In some cases, the top surface of the release layer 11 may be leveled and may have a high degree of planarity.

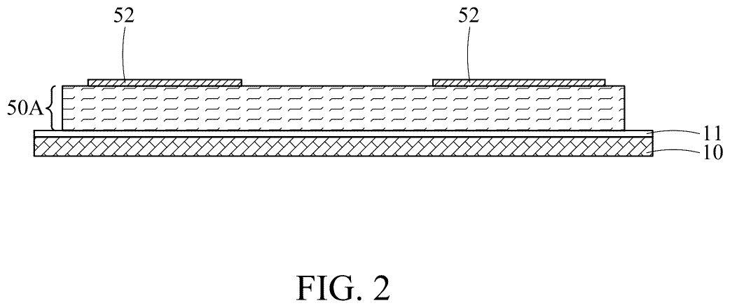

In FIG. 2, a conductive routing layer 52 is formed from the conductive pre-layer 52′, in accordance with some embodiments. The conductive routing layer 52 may include conductive routing, conductive traces, metal lines, or the like. The conductive routing layer 52 may be referred to as “routing 52” herein. In other embodiments, the routing 52 may be formed prior to attachment of the first core substrate 50A to the first carrier 10.

In some embodiments, before forming the routing 52 from the conductive pre-layer 52′, a surface preparation process may first be performed on the conductive pre-layer 52′. The surface preparation process may include cleaning the exposed surfaces of the conductive pre-layer 52′ with one or more cleaning solutions (e.g., sulfuric acid, chromic acid, neutralizing alkaline solution, water rinse etc.) to remove or reduce soil, oils, and/or native oxide films. Following cleaning, a treatment with a chemical conditioner or the like, which facilitates adsorption of an activator used during subsequent electroless plating, may be used. In some embodiments, the conditioning step may be followed by micro-etching the conductive pre-layer 52′ to micro-roughen the conductive pre-layer 52′ for better bonding between the conductive pre-layer 52′ and later-deposited conductive material.

In some embodiments, a patterned mask (not illustrated) may then be formed over the conductive pre-layer 52′. The patterned mask may be formed, for example, by coating the surface with a photoresist layer, exposing the photoresist layer to an optical pattern, and developing the exposed photoresist layer to form openings in the photoresist layer that define a pattern. The openings of the pattern in the patterned mask expose portions of the conductive pre-layer 52′ on which conductive material is subsequently deposited. The conductive material may then be deposited on the exposed regions of the conductive pre-layer 52′ using, for example, a plating process, an electroless plating process, or another process. The deposition process may selectively deposit the conductive material on the exposed regions of the conductive pre-layer 52′. The conductive material may include, for example, copper, titanium, tungsten, aluminum other metals, other alloys, or the like.

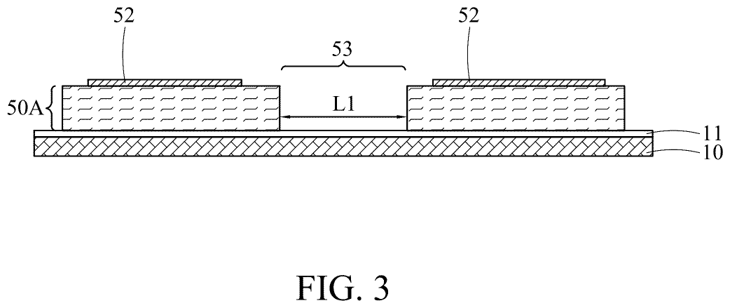

After forming the conductive material, the patterned mask (e.g., the photoresist) may be removed using, for example, a wet chemical process, a dry plasma process, an ashing process, a stripping process, or the like. Portions of the conductive pre-layer 52′ that were covered by the patterned mask may be removed along with the patterned mask or using a separate etching process. In this manner, routing 52 comprising the conductive material and remaining portions of the conductive pre-layer 52′ is formed on a side of the first core substrate 50A. In some embodiments, routing 52 is not formed in regions of the first core substrate 50A in which the cavity 53 (see FIG. 3) is subsequently formed. This is an example, and the routing 52 may be formed using other materials or techniques in other embodiments.

In FIG. 3, a cavity 53 is formed in the first core substrate 50A, in accordance with some embodiments. The cavity 53 may be formed, for example, using a laser drilling process. Other processes, e.g., mechanical drilling, etching, or the like, may also be used in other embodiments. As shown in FIG. 3, the cavity 53 may extend fully through the first core substrate 50A such that the underlying release layer 11 or first carrier 10 may be exposed. In some embodiments, the cavity 53 has a length L1 that is in the range of about 2 mm to about 11 mm, though other lengths are possible. In some embodiments, a desmear process may be performed to clean regions which may have been smeared with material of the first core substrate 50A during formation of the cavity 53. The desmearing may comprise a mechanical process (e.g., blasting with a fine abrasive in a wet slurry), a chemical process (e.g., rinsing with a combination of organic solvents, permanganate, or the like), or a combination thereof.

In FIG. 4, a component 20 is placed inside the cavity 53, in accordance with some embodiments. The component 20 may be placed inside the cavity 53 using, for example, a pick-and-place (PnP) tool or the like. In some embodiments, the component 20 may be a passive device, such as a multilayer ceramic chip (MLCC) capacitor; an integrated passive device (IPD); an integrated voltage regulator (IVR), the like, or a combination thereof. In some embodiments, the component 20 may be active device, such as a semiconductor die, an integrated circuit die, an electronic device, a memory die (e.g., a static random-access memory (SRAM) die, a dynamic random-access memory (DRAM) die, a high bandwidth memory (HBM) die, or the like), a logic chip, an analog chip, a microelectromechanical systems (MEMS) chip, a radio frequency (RF) chip, the like, or a combination thereof. Other types of components 20 are possible, and any suitable component may be considered within the scope of the present disclosure.

Although FIG. 4 illustrates one component 20 placed in the cavity 53, it should be appreciated that multiple components (e.g., multiple dies or devices) may be placed in the cavity 53 in other embodiments. For example, in some embodiments, a plurality of components may be placed laterally adjacent to one another and/or stacked upon each other, wherein the multiple components may have the same size or different sizes. Before being placed into the cavity 53, the component 20 may be processed according to applicable manufacturing processes to form the respective device structure. The component 20 may include connection terminals 21 to which external connections are made. The connection terminals 21 may comprise, for example, conductive pads, conductive pillars, conductive routing, or the like. In some embodiments, the component 20 has a thickness T2 that is in the range of about 50 μm to about 650 μm, though other thicknesses are possible. In some embodiments, a thickness T2 of the component 20 is about the same as a thickness T1 of the first core substrate 50A. In other embodiments, the thickness T2 of the component 20 is greater than or less than a thickness T2 of the first core substrate 50A. In some cases, the thickness T1 of the first core substrate 50A may be chosen to match or correspond appropriately to the thickness T3 of the subsequently-attached component 20.

In some embodiments, the component 20 has a length L2 that is in the range of about 2 mm to about 10 mm, though other lengths are possible. In some embodiments, a length L1 of the cavity 53 is larger than a length L2 of the component 20. In this manner, the component 20 may be laterally surrounded by a gap 22 between the component 20 and the first core substrate 50A. Thus, the component 20 may not physically contact the first core substrate 50A. In some embodiments, a lateral distance D1 of the gap 22 between a sidewall of the cavity 53 (e.g., a sidewall of the first core substrate 50A) and a sidewall of the component 20 is in the range of about 10 μm to about 50 μm. In some cases, the lateral distance D1 of the gap 22 at one sidewall surface of the component 20 is different from a lateral distance D1 of the gap 22 at a different sidewall surface of the same component 20. The dimensions (e.g., length, width, or area) of the cavity 53 may be greater than the dimensions of the component 20. For example, in some embodiments, the component 20 may have dimensions in the range of about 2 mm×2 mm to about 10 mm×10 mm, and the cavity 53 may have dimensions in the range of about 2 mm×2 mm to about 11 mm×11 mm. Other dimensions or areas are possible.

The component 20 may be placed on a surface of the release layer 11 exposed by the cavity 53. In some embodiments, the component 20 is adhered to the release layer 11 by an adhesive (not illustrated). The adhesive may be attached to a backside of the component 20 and may attach the component 20 to the release layer 11. The adhesive may comprise any suitable adhesive, epoxy, die attach film (DAF), or the like. In some embodiments, the adhesive may be attached to the surface of the release layer 11 prior to placing the component 20 in the cavity 53. In other embodiments, the component 20 is placed on a surface of the first carrier 10 exposed by the cavity 53, and an adhesive may be used.

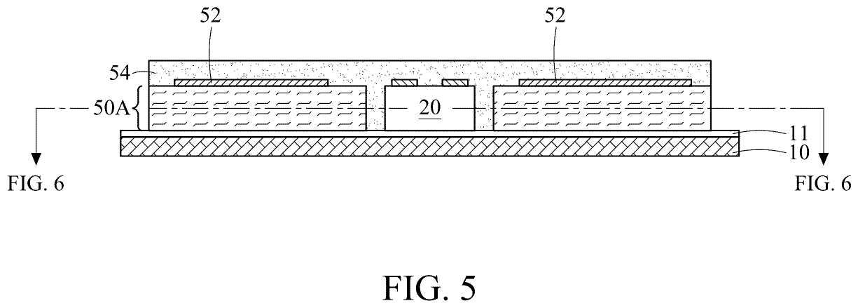

In FIG. 5, an insulating film 54 is formed over the first core substrate 50A, the component 20, and within the gap 22, in accordance with some embodiments. The insulating film 54 continuously extends over and covers the top surfaces of the first core substrate 50A and the component 20. The insulating film 54 may partially or completely fill the gap 22. In some embodiments, the insulating film 54 covers sidewalls of the first core substrate 50 and the component 20 within the gap 22. The insulating film 54 may physically contact the release layer 11, and surfaces of the first core substrate 50A, the insulating film 54, and/or the component 20 may be substantially level or coplanar. In some embodiments, the insulating film 54 may be a film of ABF, a build-up material, a prepreg material, a laminate material, another material similar to those described above for the first core substrate 50A, the like, or a combination thereof. The insulating film 54 may be formed by a lamination process, a coating process, or another suitable process. In some cases, a thermal process, a pre-curing process, or the like may be performed on the insulating film 54 after forming the insulating film 54. In some cases, the thermal process may facilitate the flow of insulating film 54 material into the gap 22. In some embodiments, the insulating film 54 may have a thickness over the first core substrate 50A that is in the range of about 5 μm to about 50 μm, though other thicknesses are possible. In some cases, the structure shown in FIG. 5 may be considered a “core structure.”

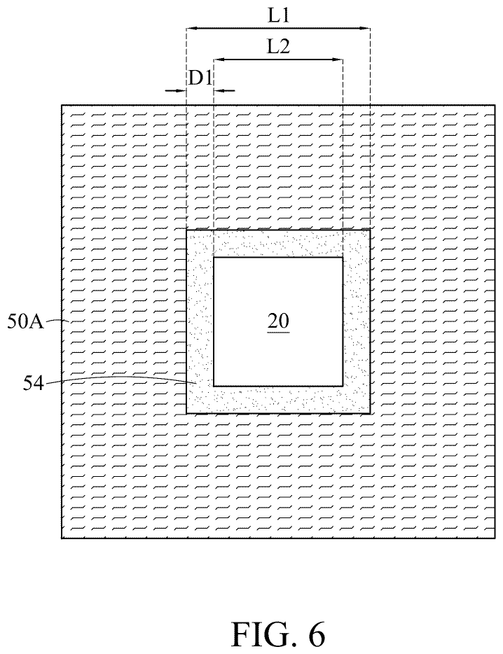

FIG. 6 illustrates a plan view of a structure similar to that shown in the cross-sectional view of FIG. 5, in accordance with some embodiments. For example, the plan view of FIG. 6 may be along a cross-section similar to the cross-section indicated as “FIG. 6” in FIG. 5. As shown in FIG. 6, the component 20 may be laterally surrounded by the insulating film 54. In this manner, the insulating film 54 separates the component 20 from the first core substrate 50A. The component 20 and the surrounding region of insulating film 54 are shown in FIG. 6 as having square shapes in a plan view, but rectangular, curved, rounded, ovoid, other shapes, or irregular shapes are possible. The structure shown in FIG. 6 is an illustrative example, and the various features may have different relative or absolute sizes or dimensions that shown.

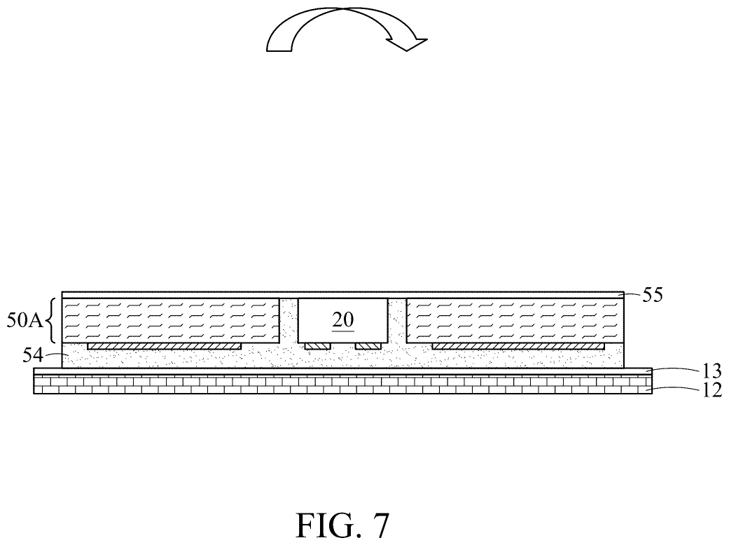

In FIG. 7, the first carrier 10 is removed (“de-bonded”) from the structure, then the structure is flipped over and attached to a second carrier 12, in accordance with some embodiments. In some embodiments, the de-bonding includes projecting a light such as a laser light or an UV light on the release layer 11 such that the release layer 11 decomposes under the heat of the light and the first carrier 10 can be removed. The structure is then flipped over and placed on a second carrier 12, which may be similar to the first carrier 10. For example, the second carrier 12 may be a wafer, a tape, or another type of carrier. The structure may be attached to the second carrier 12 using a release layer 13, which may be similar to the release layer 11 described previously. For example, the insulating film 54 of the structure may be attached to the second carrier 12 by a release layer 13. In other embodiments, a release layer 13 is not present.

After attaching the structure to the second carrier 12, an adhesive layer 55 is deposited over the structure, in accordance with some embodiments. The adhesive layer 55 may comprise any suitable adhesive, epoxy, die attach film (DAF), prepreg layer, or the like. As shown in FIG. 7, the adhesive layer 55 covers surfaces of the first core substrate 50A, the insulating film 54, and the component 20. In some embodiments, the adhesive layer 55 has a thickness in the range of about 20 μm to about 40 μm, though other thicknesses are possible.

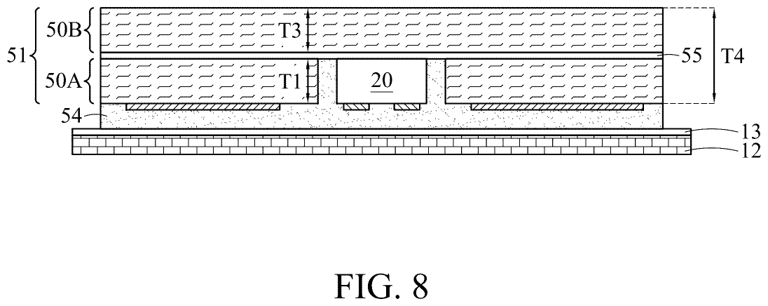

In FIG. 8, a second core substrate 50B is attached (e.g., “bonded”) to the structure using the adhesive layer 55, in accordance with some embodiments. The second core substrate 50B may be similar to the first core substrate 50A. For example, the second core substrate 50B may comprise ABF, build-up materials, laminate materials, fiberglass-reinforced resin materials, or the like. The second core substrate 50B may be placed on the adhesive layer 55 to bond the second core substrate 50B to the first core substrate 50A. The structure comprising the first core substrate 50A bonded to the second core substrate 50B may be referred to herein as the “multi-stack core substrate 51,” and may also be considered a “bonded core substrate,” or the like. In some cases, the first core substrate 50A may be considered the “upper core” and the second core substrate 50B may be considered the “lower core.” In some embodiments, no metal (e.g., conductive layers, routing, or the like) is present between the first core substrate 50A and the second core substrate 50B of the multi-stack core substrate 51. In some embodiments, a conductive layer or routing may be formed on the non-attached side of the second core substrate 50B before or after attachment of the second core substrate 50B.

In some embodiments, the second core substrate 50B may have a thickness T3 that is about the same as or greater than a thickness T1 of the first core substrate 50A. In some embodiments, the total thickness T4 of the multi-stack core substrate 51 (e.g., the total thickness of the first core substrate 50A, the adhesive layer 55, and the second core substrate 50B) is about 1200 μm or greater, though other thicknesses are possible. Forming a multi-stack core substrate 51 that is at least 1200 μm thick can provide improved rigidity and reduced warping for the subsequently-formed package substrate structure 70 (see FIG. 13). In some cases, the thickness T3 of the second core substrate 50B may be chosen to correspond appropriately to the thickness T1 of the first core substrate 50A to provide a suitable thickness T4 for the multi-stack core substrate 51. In some embodiments, the second core substrate 50B may have a thickness T3 that is in the range of about 500 μm to about 1200 μm, though other thicknesses are possible.

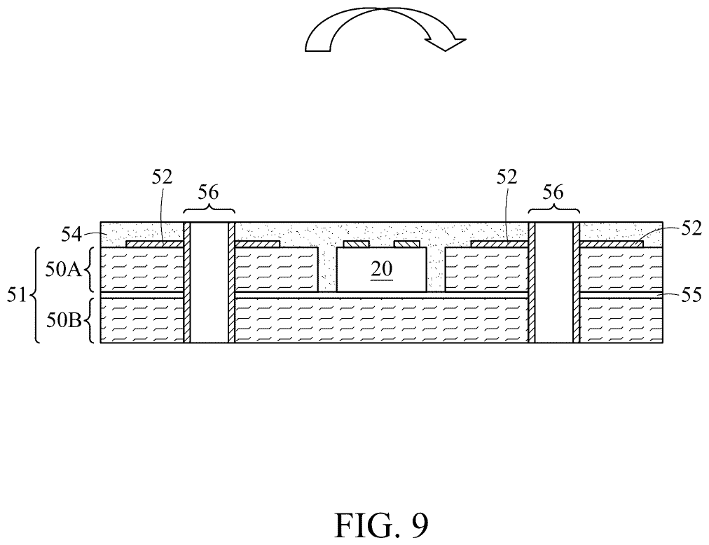

In FIG. 9, the second carrier 12 is removed from the structure and through vias 56 are formed, in accordance with some embodiments. The second carrier 12 may be removed, for example, by removing the release layer 13 using techniques similar to those described for the release layer 11. In FIG. 9, the structure has been flipped from the orientation of FIG. 8. After removing the second carrier 12, through vias 56 are formed extending through the structure, in accordance with some embodiments. The through vias 56 allow for electrical connections between opposite sides of the structure. In some cases, a through via 56 may be physically and electrically connected to a portion of routing 52. In some cases, the through vias 56 may be considered plated through-holes (PTH), conductive conduits, or the like.

The through vias 56 may be formed, for example by forming openings (not separately illustrated) extending through the structure. The openings may extend completely through the insulating film 54 and the multi-stack core substrate 51. In some embodiments, the openings are formed by laser drilling. Other processes such as mechanical drilling, etching, or the like may also be used. The openings may have a rectangular, circular, or other shape in a top-down view. After forming the openings, a desmear process may be performed, which may be similar to the desmear process described previously. In some cases, a surface preparation process such as a cleaning process may be performed on the structure and within the openings, which may be similar to the surface preparation process described previously. In some cases, a conditioning step and/or a micro-etching step may be performed on the structure and within the openings, which may be similar to those described previously.

After forming the openings, a patterned mask (not separately illustrated) may be formed over the structure. In some embodiments, a conductive pre-layer (e.g., a copper layer, a metal foil, a seed layer, or the like) may be deposited on the structure and within the openings prior to formation of the patterned mask. The patterned mask may be formed, for example, by coating the surface with a photoresist layer, exposing the photoresist layer to an optical pattern, and then developing the exposed photoresist layer to form openings in the photoresist layer that define a pattern of the region where conductive material may be deposited. For example, the openings in the patterned photoresist layer may correspond to the openings in the structure. A conductive material is then deposited on sidewalls of the openings in the structure using, for example, a plating process, an electroless plating process, or another process. The conductive material may also be deposited on portions of the routing 52 exposed by the openings. For embodiments in which the conductive pre-layer is formed in the openings, the conductive material is deposited on the conductive pre-layer on the sidewalls of the openings. The conductive material may comprise, for example, copper, other metals, metal alloys, the like, or a combination thereof. After depositing the conductive material, the patterned mask (e.g., the photoresist) may be removed using a wet chemical process or a dry process (e.g., an ashing process). Portions of the conductive pre-layer (if present) that were covered by the patterned mask may be removed with the patterned mask or using a separate etching process.

In some embodiments, after forming the conductive material along sidewalls of the openings, the openings may then be filled with a dielectric material, as illustrated in FIG. 9. The dielectric material may provide structural support, insulation, and protection for the conductive material. In some embodiments, the dielectric material may be an insulating material such as a molding material, epoxy, an epoxy molding compound, a resin, the like, or a combination thereof. The dielectric material may be formed using, e.g., a spin-on process, a lamination process, a deposition process, an encapsulation process, or another process. In some embodiments, the conductive material may completely fill the through vias 56, omitting the dielectric material. In some embodiments, a planarization process, such as a chemical mechanical polish (CMP) process, a grinding process, or the like, may be performed to remove excess material from surfaces of the insulating film 54 and/or the second core substrate 50B. In some embodiments, surfaces of the through vias 56 and the insulating film 54 may be substantially level or coplanar, and surfaces of the through vias 56 and the second core substrate 50B may be substantially level or coplanar.

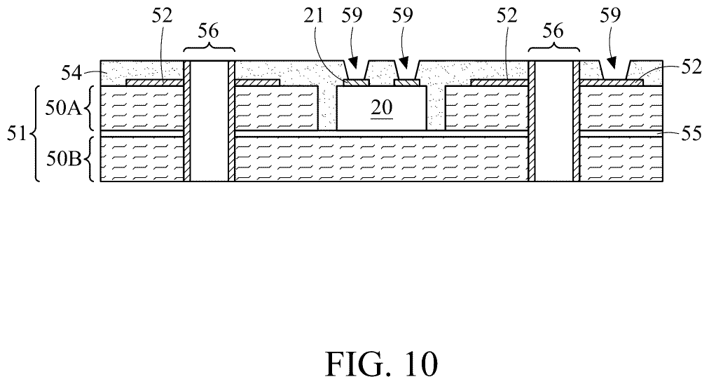

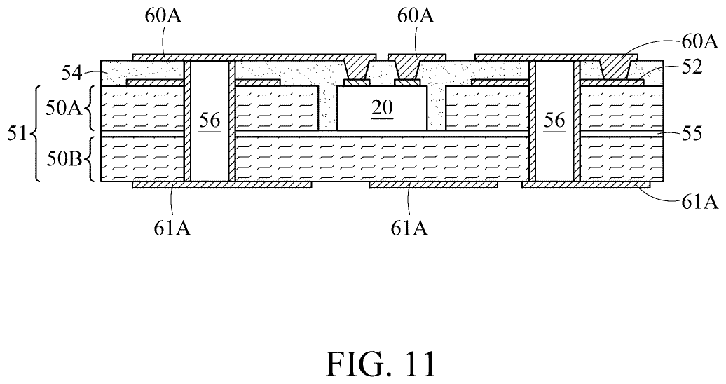

In FIG. 10, via openings 59 are formed in the insulating film 54 that expose the connection terminals 21 of the component 20 and/or the routing 52, in accordance with some embodiments. Via portions of the subsequently formed routing 60A (see FIG. 11) are formed in the via openings 59 to make electrical connection to the component 20 and/or the routing 52. In some embodiments, the via openings 59 are formed using, for example, a laser drilling technique. Other processes, e.g., mechanical drilling, etching, or the like, may also be used in other embodiments. In some embodiments, a desmear process or other cleaning process may be performed after forming the via openings 59.

In FIG. 11, a conductive routing layer 60A (e.g., “routing 60A”) and a conductive routing layer 61A (e.g., “routing 61A”) are formed on opposite sides of the structure, in accordance with some embodiments. The routing 60A is formed over the insulating film 54 and through vias 56 on one side of the structure (e.g., the “top side”), and the routing 61A is formed over the second core substrate 50B and through vias 56 on the opposite side of the structure (e.g., the “bottom side”). In some embodiments, conductive pre-layers (not shown) may be formed over each side of the structure, which may act as seed layers for forming conductive material (described below). The conductive pre-layers may be similar to that described previously for FIG. 9. For example, a conductive pre-layer may be e.g., a metal foil such as a copper foil, or another type of material such as those described above for routing 52. In other embodiments, the conductive pre-layers may be formed over the structure before forming the via openings 59. In other embodiments, conductive pre-layers are not formed.

In some embodiments, the routing 60A is formed by first forming a patterned mask over the top side of the structure. The patterned mask may be, for example, a patterned photoresist layer. Openings in the patterned mask may expose portions of the conductive pre-layer on which conductive material will subsequently be formed. The conductive material may then be deposited on the exposed regions of the conductive pre-layer using and in the via openings 59, for example, a plating process, an electroless plating process, or another process. The conductive material may be similar to that described previously for the routing 52. After forming the conductive material, the patterned mask and portions of the conductive pre-layer on which the conductive material is not formed are then removed. After depositing the conductive material, the patterned mask (e.g., the photoresist) and underlying portions of the conductive pre-layer may be removed using one or more suitable wet chemical processes or dry processes. The remaining portions of the conductive pre-layer and the conductive material form the routing 60A. However, any suitable processes and materials may be utilized in the formation of the routing 60A.

In this manner, routing 60A may be formed over and electrically connected to the through vias 56, component 20, and/or routing 52 at the top side of the structure. The routing 60A includes conductive trace portions that extend along surfaces of the insulating film 54 and through vias 56, and conductive via portions in the via openings 59 that extend through the insulating film 54. The via portions of the routing 60A physically and electrically connect the conductive trace portions of the routing 60A to underlying conductive features, such as connection terminals 21 or routing 52.

The routing 61A may be formed on the bottom side of the structure using techniques similar to those used to form the routing 60A on the top side of the structure. For example, a patterned mask may be formed over the bottom side of the structure, with openings that expose portions of the conductive pre-layer on which conductive material will subsequently be formed. Conductive material may then be deposited on the exposed portions of the conductive pre-layer using, e.g., a plating technique. The patterned mask and underlying portions of the conductive pre-layer may then be removed, with remaining portions of the conductive material and conductive pre-layer forming the routing 61A. In other embodiments, a conductive pre-layer is not formed. In this manner, routing 61A may be formed over and electrically connected to the through vias 56 at the bottom side of the structure. The routing 61A includes conductive trace portions that extend along surfaces of the second core substrate 50B and through vias 56.

In some embodiments, some process steps of the formation of the routing 61A may be performed at the same time as process steps of the formation of the routing 60A. For example, in some embodiments, conductive material may be deposited to simultaneously form the routing 60A and the routing 61A. In some cases, the patterned mask or underlying conductive pre-layer may be simultaneously removed from the top side and the bottom side of the structure using the same process steps. In other embodiments, the conductive material of the through vias 56 is deposited simultaneously with the conductive material of the routing 60A and/or routing 61A. These are examples, and other shared process steps are possible.

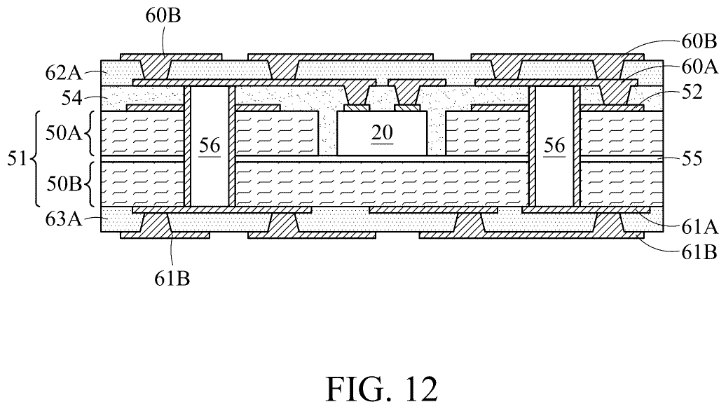

In FIG. 12, an additional layer of routing 60B is formed over the routing 60A at the top side of the structure, and an additional layer of routing 61B is formed over the routing 61A at the bottom side of the structure, in accordance with some embodiments. The routing 60B and the routing 61B may be formed using similar process steps, and some process steps of forming the routing 60B and the routing 61B may be simultaneous. In some embodiments, a build-up layer 62A is formed on the top side of the structure, and a build-up layer 63A is formed on the bottom side of the structure. For example, the build-up layer 62A is formed over the insulating film 54 and the routing 60A, and the build-up layer 63A is formed over the second core substrate 50B and the routing 61A. The build-up layer 62A and the build-up layer 63A (e.g., the “build-up layers 62A/63A”) may be similar types of build-up layer or may be different types of build-up layer. The build-up layers 62A/63A may comprise materials similar to those described previously for the insulating film 54 or first core substrate 50A, though other materials are possible. In some embodiments, within the same structure, the material of the build-up layer 62A and/or the build-up layer 63A may be different from the material of the insulating film 54. The build-up layers 62A/63A may be formed by a lamination process, a coating process, or another suitable process. In some embodiments, the build-up layer 62A and/or the build-up layer 63A may have a thickness in the range of about 5 μm to about 40 μm, though other thicknesses are possible. In some embodiments, conductive pre-layers (not shown) may be formed over the build-up layers 62A/63A, which may act as a seed layer for forming conductive material (described below). The conductive pre-layer may be similar to those described previously and may be e.g., a metal foil such as a copper foil or the like. In other embodiments, a conductive pre-layer is not formed.

In some embodiments, openings (not shown) are formed in the build-up layer 62A that expose portions of the routing 60A, and openings (not shown) are formed in the build-up layer 63A that expose portions of the routing 61A. In some embodiments, the openings are formed by, for example, a laser drilling technique. Other processes, e.g., mechanical drilling, etching, or the like, may also be used in other embodiments. In some embodiments, an optional surface preparation process (e.g., a desmear process or the like) may be performed after the openings are formed.

A conductive material is then deposited on the top side of the structure to form routing 60B on the build-up layer 62A and within the openings in the build-up layer 62A, and deposited on the bottom side of the structure to form routing 61B on the build-up layer 63A and within the openings in the build-up layer 63A. In some embodiments, the routing 60B is formed by first forming a patterned mask over the build-up layer 62A. The patterned mask may be, for example, a patterned photoresist layer. Openings in the patterned mask may expose portions of the build-up layer 62A (or, if present, a conductive pre-layer on the build-up layer 62A) on which conductive material will subsequently be formed. The openings in the patterned mask also may expose the openings in the build-up layer 62A. The conductive material may then be deposited on the exposed regions of the build-up layer 62A and within the openings in the build-up layer 62A using, for example, a plating process, an electroless plating process, or another process. After depositing the conductive material, the patterned mask (e.g., the photoresist) and underlying portions of the conductive pre-layer may be removed using one or more suitable wet chemical processes or dry processes. The remaining portions of the conductive pre-layer and the conductive material form the routing 60B. In this manner, additional routing 60B is formed over and electrically connected to the routing 60A. The routing 61B may be formed on the bottom side of the structure using techniques similar to those used to form the routing 60B on the top side of the structure, and some process steps for forming the routing 60B and the routing 61B may be shared. However, any suitable processes and materials may be utilized in the formation of the routing 60B or the routing 61B.

In FIG. 13, additional routing 60C is formed on the routing 60A to form a first routing structure 64, and additional routing 61C is formed on the routing 61B to form a second routing structure 66, in accordance with some embodiments. In this manner, a package substrate structure 70 comprising a multi-stack core substrate 51, a component 20, a first routing structure 64, and a second routing structure 66 may be formed, in accordance with some embodiments. The routing 60C and routing 61C may be similar to the routing 60A-B or routing 61A-B, and may be formed using similar techniques. For example, a build-up layer 62B may be formed over the build-up layer 62A and routing 60B, openings may be formed in the build-up layer 62B, and then conductive material may be deposited using a patterned mask to form routing 60C on and in the build-up layer 62B. Similarly, a build-up layer 63B may be formed over the build-up layer 64A and routing 61B, openings may be formed in the build-up layer 63B, and then conductive material may be deposited using a patterned mask to form routing 61C on and in the build-up layer 63B.

In some embodiments, the first routing structure 64 comprises conductive pads 67 formed on the routing 60C, and the second routing structure 66 comprises conductive pads 68 formed on the routing 66. The conductive pads 67/68 facilitate external electrical connection to the package substrate structure 70. For example, the conductive pads 67 may allow for electrical connection to the top side of the package substrate structure 70 (e.g., to the first routing structure 64) and the conductive pads 68 may allow for electrical connection to the bottom side of the package substrate structure 70 (e.g., to the second routing structure 66). In some embodiments, the conductive pads 67/68 may be under-bump metallization (UBM) structures or the like. In some embodiments, the conductive pads 67/68 may be formed using techniques similar to those described previously for the routing 60A-C and the routing 61A-C. In some cases, the conductive pads 67/68 may be considered another layer of routing, such as an “outermost” layer of routing. As an example, a build-up layer 62C may be formed over the build-up layer 62B and routing 60C, openings may be formed in the build-up layer 62C, and then conductive material may be deposited using a patterned mask to form conductive pads 67 on and in the build-up layer 62C. Similarly, a build-up layer 63C may be formed over the build-up layer 63B and routing 61C, openings may be formed in the build-up layer 63C, and then conductive material may be deposited using a patterned mask to form conductive pads 68 on and in the build-up layer 63C. The conductive pads 67 may have a different size or pitch than the conductive pads 68, in some embodiments. In some embodiments, a passivation layer, a solder resist layer, and/or the like (not separately illustrated) may be formed over an outermost build-up layer (e.g., build-up layer 62C or 63C).

In this manner, a first routing structure 64 is formed on a top side of the multi-stack core substrate 51 and a second routing structure 64 is formed on a bottom side of the multi-stack core substrate 51, in accordance with some embodiments. Accordingly, the multi-stack core substrate 51 is sandwiched between the first routing structure 64 and the second routing structure 66. The through vias 56 electrically connect the first routing structure 64 to the second routing structure 66. The first routing structure 64 is shown having three layers of routing 60A-C and the second routing structure 66 is shown having three layers of routing 61A-C, but a routing structure 64/66 may have any suitable number of routing layers. The build-up layers of a routing structure 64/66 may all be formed of the same material, or the build-up layers of a routing structure 64/66 may be formed of different materials. In some cases, a routing structure 64/66 may be considered an interconnect structure, a redistribution structure, or the like. As shown in FIG. 13, the first routing structure 64 is physically and electrically connected to the component 20 (e.g., by routing 60A), but the second routing structure 66 is not physically connected to the component 20 and is separated from the component 20 by the second core substrate 50B. In some embodiments, the package substrate structure 70 may be pressed or subjected to a thermal treatment. The package substrate structure 70 shown in FIG. 13 is an example, and other configurations are possible.

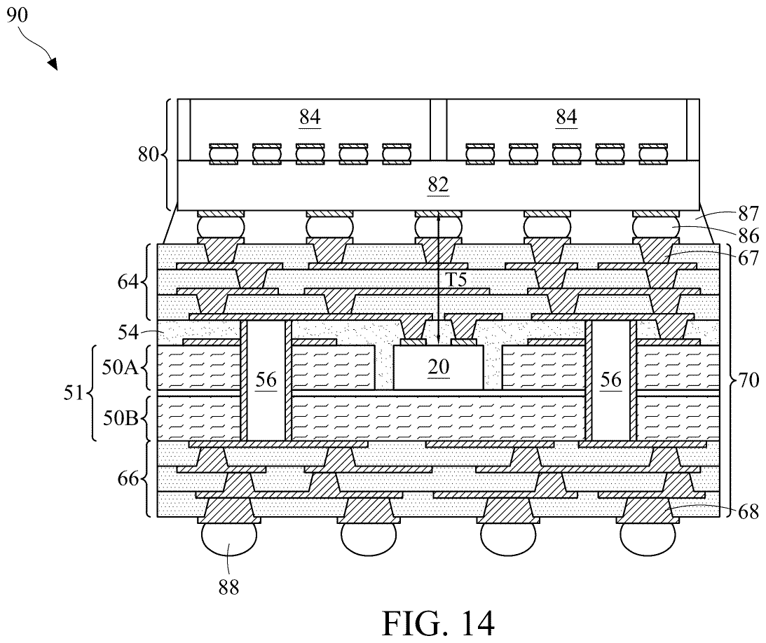

The package substrate structure 70 may be incorporated into other packages or structures. The package substrate structure 70 may be incorporated into, for example, an integrated fan-out (InFO) package, a chip-on-wafer-on-substrate (CoWoS) package, another type of package, or the like. As a non-limiting example, FIG. 14 illustrates a package 90 incorporating a package substrate structure 70, in accordance with some embodiments. In FIG. 14, a package component 80 is attached (e.g., bonded) to the package substrate structure 70, in accordance with some embodiments.

The package component 80 may comprise, for example, a die, a chip, a semiconductor device, a stacked die, an electronic die, a chip-on-wafer (CoW) structure, a component, the like, or any other suitable structure. In the example of FIG. 14, the package component 80 comprises a plurality of dies 84 attached to an interposer 82. The dies 84 may be devices similar to those described previously for the component 20. For example, in some embodiments, the dies 84 may comprise logic dies and memory dies, though other combinations of dies 84 are possible. The interposer 82 may comprise conductive routing (not separately illustrated) formed in or on a wafer (e.g., a silicon wafer), a core substrate, or the like. In some cases, the interposer 83 may be another type of interposer, such as a redistribution interposer, or the like. The interposer 82 may have through vias or the like (not separately illustrated). The interposer 82 may be free of active and/or passive devices, in some cases. The dies 84 may be attached to the interposer by conductive connectors (e.g., solder bumps or the like) or using direct bonding, such as fusion bonding or metal-to-metal bonding. The package component 80 is an illustrative example, and other package components are possible.

The package component 80 may be attached to the package substrate structure 70 by conductive connectors 86, in accordance with some embodiments. For example, the conductive connectors 86 may physically and electrically connect conductive pads 67 of the package substrate structure 70 to the package component 80. The conductive connectors 86 may be ball grid array (BGA) connectors, solder balls, metal pillars, solder bumps, controlled collapse chip connection (C4) bumps, micro bumps, electroless nickel-electroless palladium-immersion gold technique (ENEPIG) formed bumps, or the like. The conductive connectors 86 may include a conductive material such as solder, copper, aluminum, gold, nickel, silver, palladium, tin, the like, or a combination thereof. In some embodiments, the conductive connectors 86 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 86 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, the package component 80 may be arranged on the package substrate structure 70 such that conductive connectors 86 of the package component 80 are placed in contact with conductive pads 67 of the package substrate structure 70. Once arranged, a reflow process may be performed to bond the package component 80 to the package substrate structure 70. In other embodiments, the package component 80 may be bonded to the package substrate structure 70 using direct bonding, such as fusion bonding or metal-to-metal bonding.

An underfill 87 may be optionally be formed between the package component 80 and the package substrate structure 70, in some embodiments. The underfill 87 may surrounding the conductive connectors 86. The underfill 87 may be formed using, for example, a capillary underfill process after the package component 80 has been attached. Other deposition techniques are possible. In some embodiments, conductive connectors 88 may be formed on the conductive pads 68. The conductive connectors 88 may be similar to the conductive connectors 86 described previously. In some embodiments, an integrated passive device (IPD) or the like (not separately illustrated) may be attached to the conductive pads 68. The package 90 shown in FIG. 14 is an example, and other packages 90 are possible.

The use of a multi-stack core substrate 51 as described herein allows for one or more components 20 to be incorporated into a package substrate structure 70 of a package 90 while allowing the package substrate structure 70 to maintain suitable rigidity. In this manner, yield, design flexibility, and device functionality may be improved. FIG. 14 illustrates that the component 20 is electrically connected to the package component 80 through the first routing structure 64. Disposing the component 20 in the cavity 53 of the multi-stack core substrate 51 allows a distance between the component 20 and the package component 80 to be reduced. Reducing this distance can reduce a voltage drop between the component 20 and the package component 80, which can improve the power integrity, efficiency, and performance of the package 90. In some embodiments, a distance T5 between the component 20 and the package component 80 may be in the range of about 130 μm to about 490 μm, though other distances are possible. The distance T5 may depend on the number of routing layers and/or the number of build-up layers in the first routing structure 64. Forming a component 20 within a multi-stack core substrate 51 as described herein can also reduce the amount of routing of a package and reduce the overall size of a package.

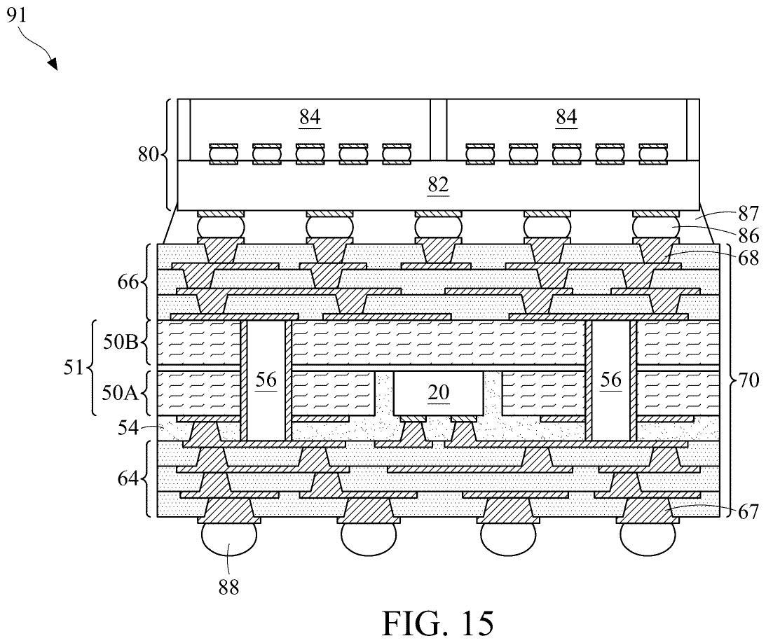

FIG. 14 illustrates the package component 80 attached to the first routing structure 64 of a package substrate structure 70, but in other embodiments, the package component 80 may be attached to the second routing structure 66 of a package substrate structure 70. Accordingly, an example of a package 91 is illustrated in FIG. 15. The package 91 is similar to the package 90 of FIG. 14, except that the package component 80 is attached to the “bottom side” of the package substrate structure 70 rather than to the “top side” of the package substrate structure 70. In this manner, the component 20 may be electrically connected to the package component 80 through the first routing structure 64, the through vias 56, and the second routing structure 66. The package 91 of FIG. 15 is an illustrative example, and other configurations are possible. Similar to the package substrate structures 90/91, other embodiment package substrate structures described herein may have a package component 80 attached at either side.

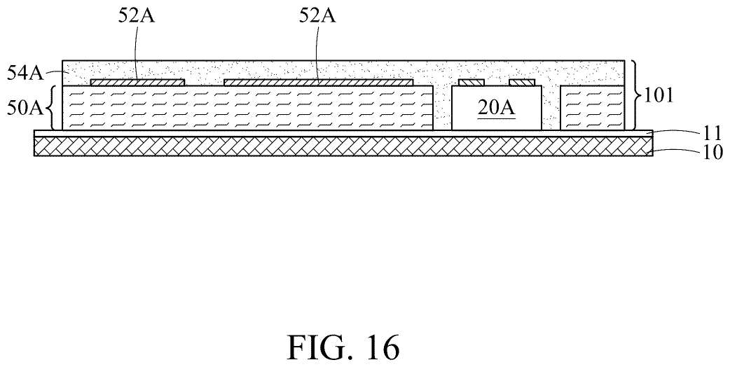

FIGS. 16 through 23 illustrate cross-sectional views of intermediate steps in the formation of a package substrate structure 100, in accordance with some embodiments. The package substrate structure 100 is similar to the package substrate structure 70 of FIG. 13, except that a first component 20A is placed within the first core substrate 50A and a second component 20B is placed within the second core substrate 50B. Some materials, techniques, and/or process steps used to form the package substrate structure 100 may be similar to those used to form the package substrate structure 70, and accordingly some details may not be repeated below.

FIG. 16 illustrates a first core structure 101, in accordance with some embodiments. The first core structure 101 may be similar to the core structure previously described for FIG. 5, and may be formed using similar techniques. For example, the first core structure 101 may be formed by forming a cavity in a first core substrate 50A, and placing the first component 20A into the cavity. The first component 20A may be attached using an adhesive or the like (not separately illustrated). Routing 52A may be formed over the first core substrate 50A, in some cases. An insulating film 54A may then be formed over the first core substrate 50A, over the first component 20A, and within the cavity. The insulating film 54A may be similar to the insulating film 54 described previously for FIG. 5. For example, in some embodiments, the insulating film 54 comprises ABF, but other materials are possible.

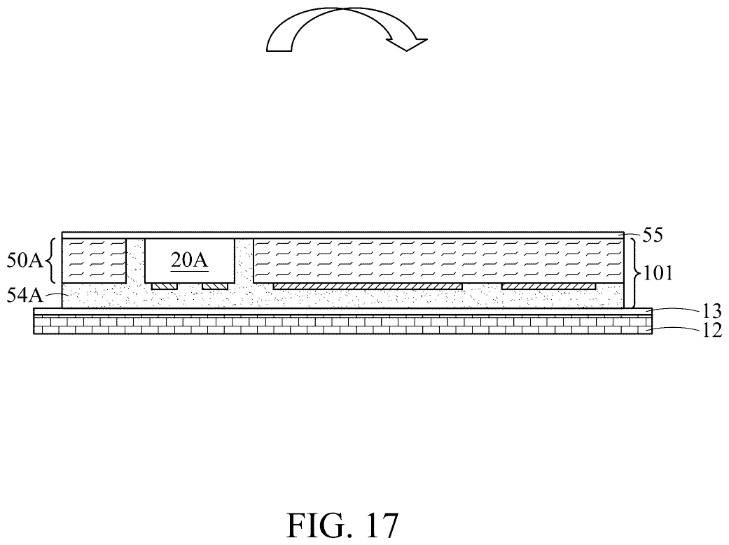

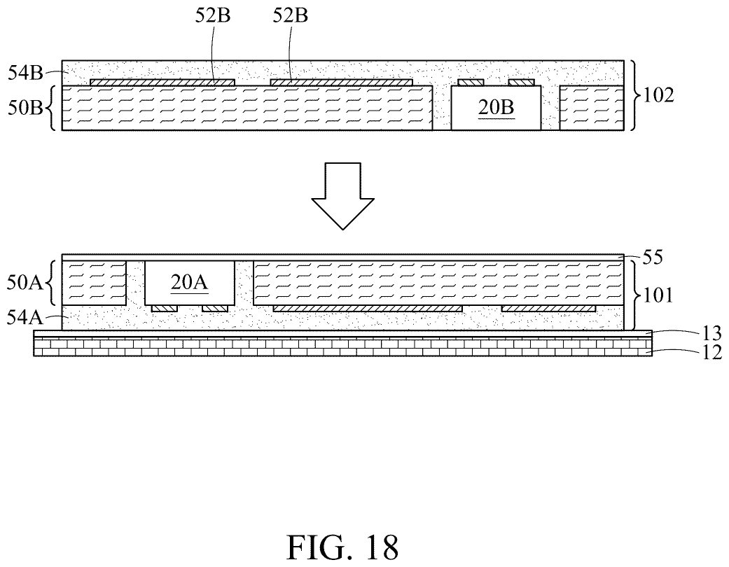

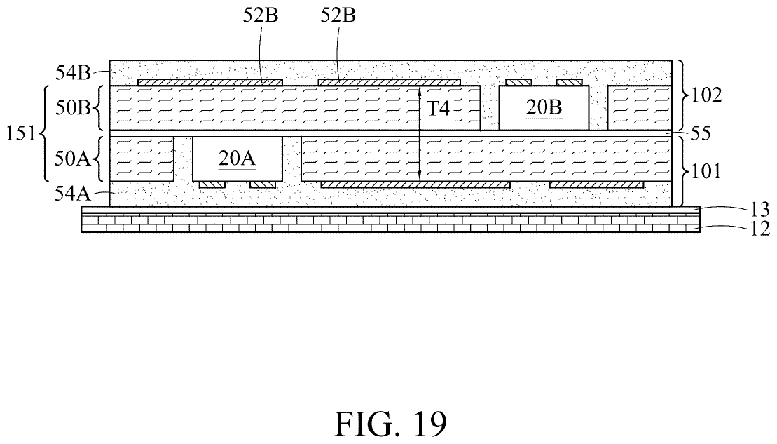

In FIG. 17, the first core structure 101 is flipped upside down and an adhesive layer 55 is formed over the first core substrate 50A and the first component 20A. The adhesive layer 55 may be similar to that described previously for FIG. 7. In FIGS. 18 and 19, a second core structure 102 is attached to the first core structure 101 using the adhesive layer 55, in accordance with some embodiments. FIG. 18 illustrates the second core structure 102 prior to attachment, and FIG. 19 illustrates the second core structure 102 after attachment to the first core structure 101. The second core structure 102 may be similar to the first core structure 101, and may be formed using similar techniques. For example, the second core structure 102 may be formed by forming a cavity in a second core substrate 50B, and placing a second component 20B into the cavity. The second component 20B may be attached using an adhesive or the like (not separately illustrated). Routing 52B may be formed over the second core substrate 50B, in some cases. An insulating film 54B may then be formed over the second core substrate 50B, over the second component 20B, and within the cavity. The insulating film 54B may be similar to the insulating film 54A, in some cases.

The first component 20A and the second component 20B may be similar components or different components. The sizes of the cavities and/or the components of each core structure 101/102 may be similar or different. One or both of the core structures 101/102 may comprise two or more components in other embodiments. The core substrates 50A/50B may have similar thicknesses or different thicknesses. Referring to FIG. 19, the first core substrate 50A bonded to the second core substrate 50B forms a multi-stack core substrate 151, in accordance with some embodiments. In some embodiments, a thickness T4 of the multi-stack core substrate 151 may be about 1200 μm or greater in order to maintain suitable rigidity and structural support. Other thicknesses are possible. The first component 20A and the second component 20B may be laterally offset (as illustrated in FIG. 19), or may be laterally aligned (e.g., overlapping). As shown in FIG. 19, the first component 20A and the second component 20B are positioned “back-to-back” and are separated by the adhesive layer 55.

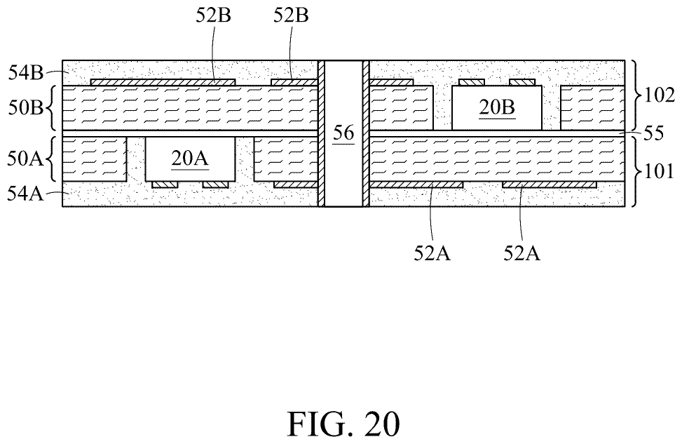

In FIG. 20, one or more through vias 56 are formed extending through the structure, in accordance with some embodiments. FIG. 20 shows a single through via 56, but multiple through vias 56 may be formed in other embodiments. The through vias 56 may be similar to those described previously for FIG. 9, and may be formed using similar techniques. For example, an opening extending through the structure may be formed, and then a conductive material may be deposited within the opening to form a through via 56. The opening may then be filled with a dielectric material. In some cases, the through vias 56 may physically and electrically connect to the routing 52A and/or 52B.

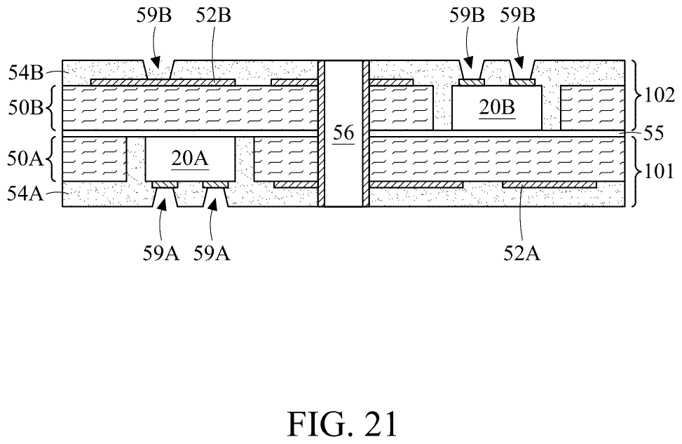

In FIG. 21, openings 59A may be formed in the insulating film 54A, and openings 59B may be formed in the insulating film 54B, in accordance with some embodiments. The openings 59A-B may be similar to the openings 59 described previously for FIG. 10, and may be formed using similar techniques, such as using a laser drilling process. For example, the openings 59A may expose the routing 52A and/or connection terminals of the first component 20A, and the openings 59B may expose the routing 52B and/or connection terminals of the second component 20B.

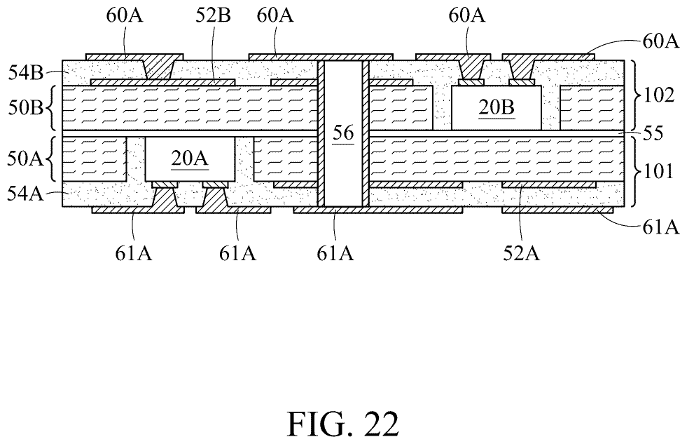

In FIG. 22, a layer of routing 60A is formed on and in the insulating film 54B, and a layer of routing 61A is formed on and in the insulating film 54A. The routing 60A/61A may be formed using materials and techniques similar to that described previously for FIG. 11. For example, patterned masks may be formed over the insulating films 54A/54B, and then conductive material may be deposited over the insulating films 54A/54B and within the openings 59A-B. In some embodiments, forming the routing 60A/61A may comprise forming a conductive pre-layer over the insulating films 54A/54B. The routing 60A may be electrically connected to the second component 20B and/or a through via 56, and the routing 61A may be electrically connected to the first component 20A and/or a through via 56.

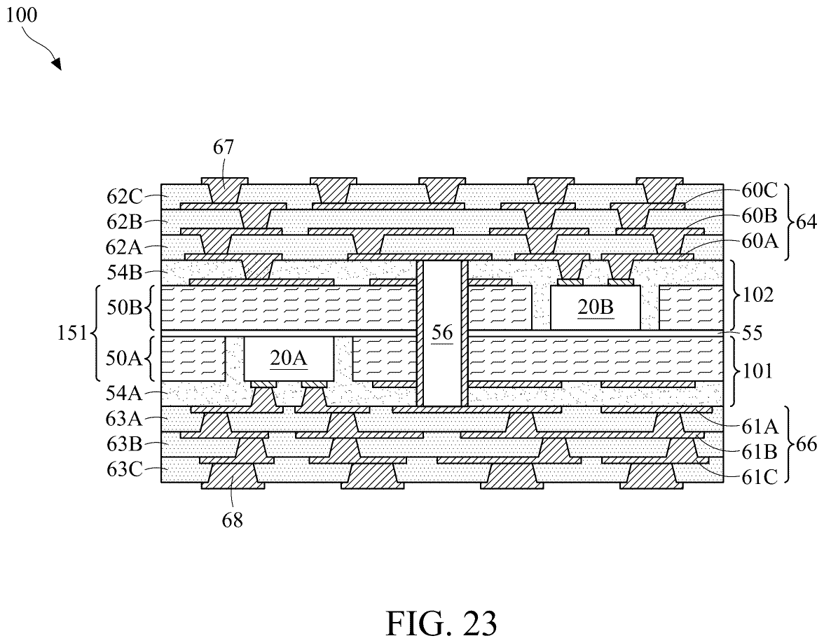

In FIG. 23, additional routing 60B-C is formed over the routing 60A to form a first routing structure 64, and additional routing 61B-C is formed over the routing 61A to form a second routing structure 66, in accordance with some embodiments. The additional routing 60B-C of the first routing structure 64 and the additional routing 61B-C of the second routing structure 66 may be formed using similar materials and techniques as described previously for FIGS. 12-13. For example, to form the routing 60B, a build-up layer 62A may be formed over the insulating film 54B and routing 60A, openings may be formed in the build-up layer 62A, and then conductive material may be deposited using a patterned mask to form routing 60B on and in the build-up layer 62B. The routing 61B may be formed similarly on and in a build-up layer 63A over the routing 61A and the insulating film 54A. Additional layers of routing (e.g., routing 60C and 61C) may be formed by repeating similar processes with additional build-up layers (e.g., build-up layers 62B and 63B). The first routing structure 64 may comprise conductive pads 67, and the second routing structure 66 may comprise conductive pads 68. The conductive pads 67/68 may be formed using materials or techniques described previously for FIG. 13. The routing structures 64/66 may comprise another number of build-up layers and/or routing than shown.

In this manner, a package substrate structure 100 may be formed, in accordance with some embodiments. Additional process steps may be performed, such as attaching a package component (e.g., package component 80 of FIGS. 14-15) to conductive pads or forming conductive connectors on conductive pads. The techniques described herein allow for the formation of a package substrate structure comprising multiple components, which can reduce package size, improve design flexibility, improve package functionality, improve package efficiency, and improve package performance.

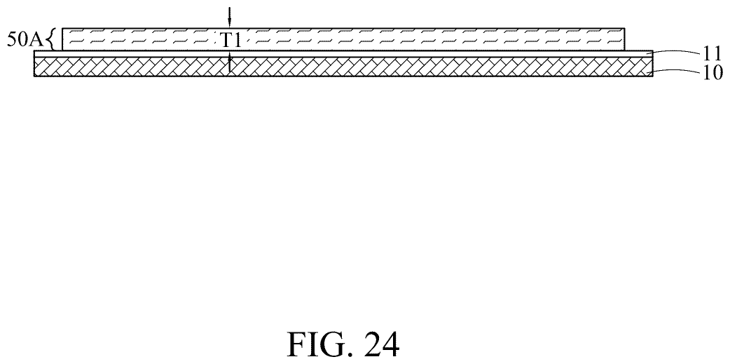

FIGS. 24 through 35 illustrate cross-sectional views of intermediate steps in the formation of a package substrate structure 200, in accordance with some embodiments. The package substrate structure 200 is similar to the package substrate structure 70 of FIG. 13, except that the component 20 is thicker than the first core substrate 50A, and multiple insulating films with routing are formed. Additionally, the second core substrate 50B may be thicker than the first core substrate 50A, forming an “asymmetrical” multi-stack core substrate 251. Some materials, techniques, and/or process steps used to form the package substrate structure 200 may be similar to those used to form the package substrate structure 70, and accordingly some details may not be repeated below.

FIG. 24 illustrates a first core substrate 50A attached to a first carrier 10, in accordance with some embodiments. The first core substrate 50A may be attached using a release layer 11 or the like. The first core substrate 50A, the first carrier 10, and the release layer 11 may be similar to those described previously for FIG. 1. In some embodiments, the first core substrate 50A may have a thickness T1 that is in the range of about 50 μm to about 650 μm, though other thicknesses are possible. In other embodiments, a conductive pre-layer 52′ or routing 52 may be formed on a top side of the first core substrate 50A.

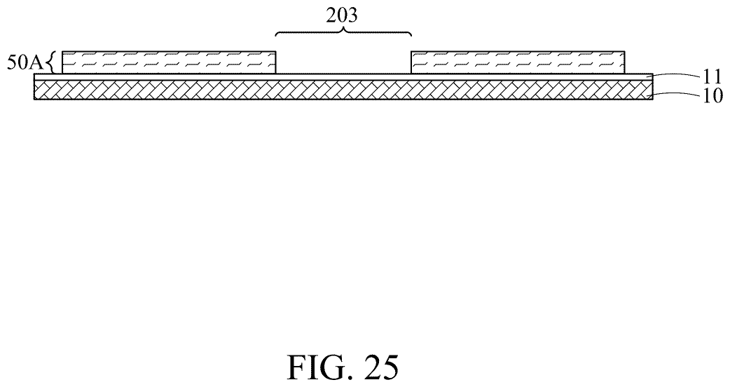

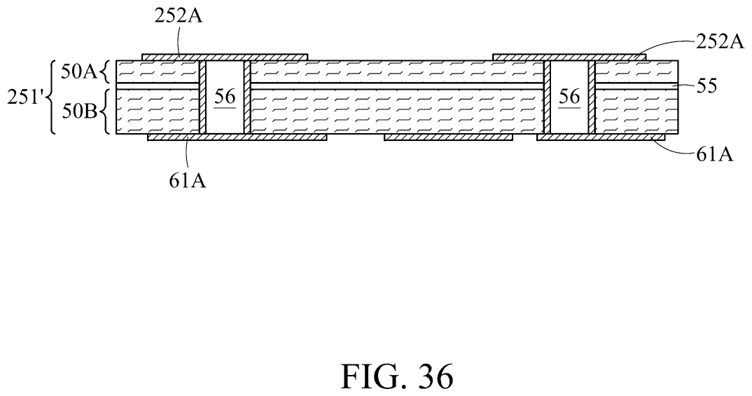

In FIG. 25, a cavity 203 is formed in the first core substrate 50A, in accordance with some embodiments. The cavity 203 may be formed using techniques similar to those described for forming the cavity 53 in FIG. 3. For example, the cavity 203 may be formed using a laser drilling process or the like. In some embodiments, a desmear process or other cleaning process may be performed after forming the cavity 203. The cavity 203 may extend completely through the first core substrate 50A, as shown in FIG. 25. In other embodiments, a cavity is formed through the first core substrate 50A at a later step, and an example embodiment of such is described below for FIGS. 36-41.

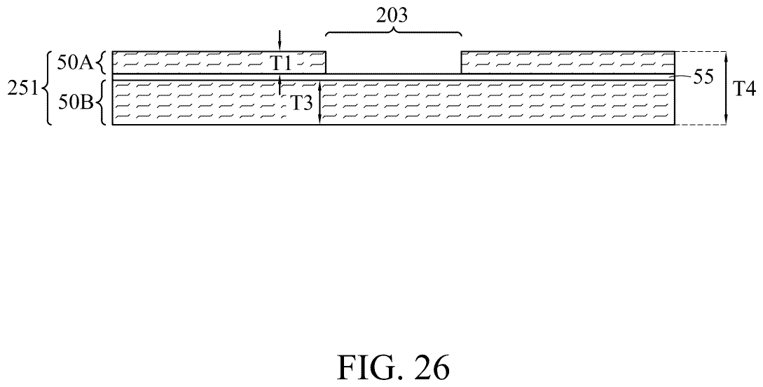

In FIG. 26, the first core substrate 50A is debonded from the first carrier 10, and a second core substrate 50B is attached to the first core substrate 50A, in accordance with some embodiments. The second core substrate 50B may be attached to the first core substrate 50A using an adhesive layer 55 or the like. The second core substrate 50B may be similar to the first core substrate 50A, except that the second core substrate 50B has a thickness T3 that is larger than a thickness T1 of the first core substrate 50B. The first core substrate 50A attached to the second core substrate 50B forms a multi-stack core substrate 251, in accordance with some embodiments. In some embodiments, a thickness T4 of the multi-stack core substrate 251 may be about 1200 μm or greater in order to maintain suitable rigidity and structural support. Accordingly, the thickness T3 of the second core substrate 50B may be chosen to correspond appropriately to the thickness T1 of the first core substrate 50A to provide a suitable thickness T4 for the multi-stack core substrate 251. In some embodiments, the second core substrate 50B may have a thickness T3 that is in the range of about 500 μm to about 1200 μm. Other thicknesses are possible. After bonding the first core substrate 50A to the second core substrate 50B, surfaces of the adhesive layer 55 may be exposed within the cavity 203, in some embodiments.

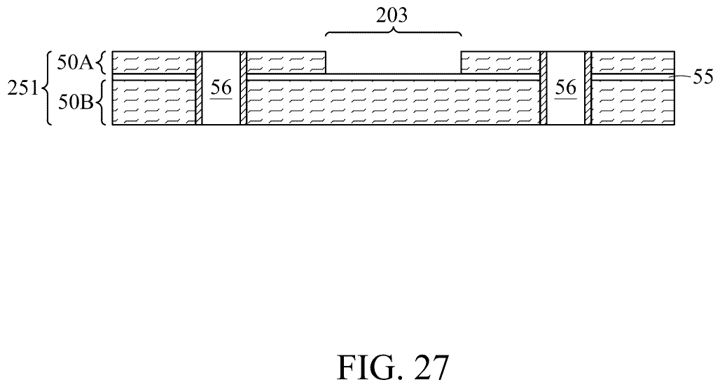

In FIG. 27, one or more through vias 56 are formed extending through the multi-stack core substrate 251, in accordance with some embodiments. The through vias 56 may be similar to those described previously for FIG. 9, and may be formed using similar techniques. For example, openings extending through the multi-stack core substrate 251 may be formed, and then a conductive material may be deposited within the openings to form the through vias 56. The openings may then be filled with a dielectric material.

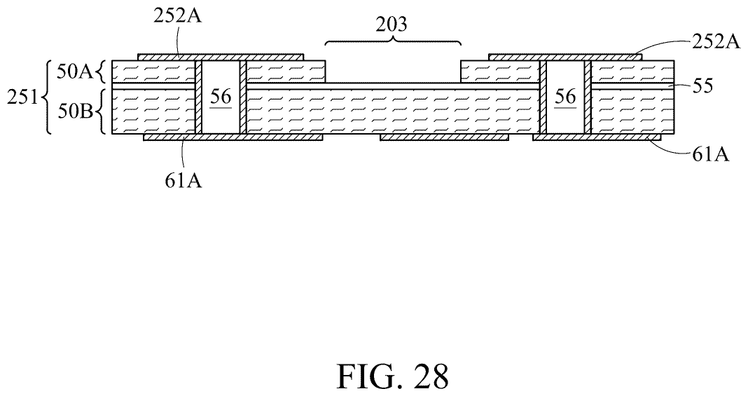

In FIG. 28, routing 252A and routing 61A are formed on the multi-stack core substrate 251, in accordance with some embodiments. The routing 252A is formed on the first core substrate 50A (e.g., on the top side of the multi-stack core substrate 251), and the routing 61A is formed on the second core substrate 50B (e.g., on the bottom side of the multi-stack core substrate 251). The routing 252A and the routing 61A (e.g., the routing 252A/61A) may be formed using techniques similar to those used to form the routing 61A as described for FIG. 11. For example, patterned masks may be formed over the core substrates 50A/50B, and then conductive material may be deposited over the core substrates 50A/50B using the patterned masks. In some embodiments, forming the routing 252A/61A may comprise forming a conductive pre-layer over the core substrates 50A/50B. The routing 252A and/or the routing 61A may be electrically connected to the through vias 56.

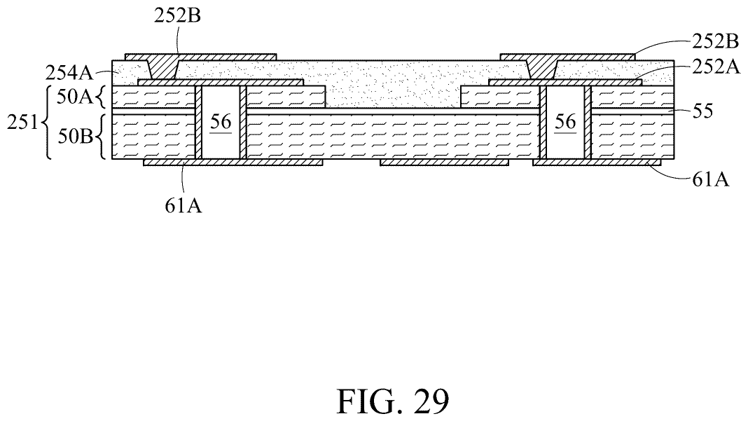

In FIG. 29, an insulating film 254A is formed over the first core substrate 50A and in the cavity 203, in accordance with some embodiments. Additionally, a layer of routing 252B is formed on and in the insulating film 254, in accordance with some embodiments. The insulating film 254A may be similar to the insulating film 54 described previously for FIG. 5. For example, in some embodiments, the insulating film 254A comprises ABF, but other materials are possible. The insulating film 254A fills the cavity 203 and may cover surfaces of the adhesive layer 55, in some embodiments. The routing 252B may be formed using techniques similar to those used to form the routing 60A as described for FIG. 11. The routing 252B extends on and in the insulating film 254A, and physically and electrically connects the routing 252A.

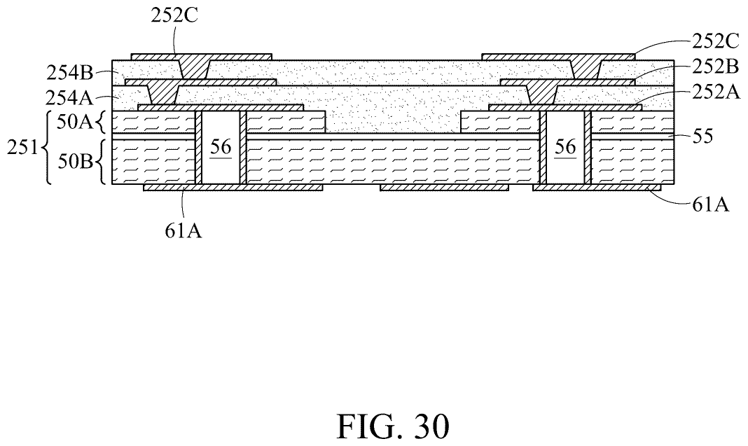

In FIG. 30, an insulating film 254B and routing 252C is formed over the insulating film 254A and the routing 252B, in accordance with some embodiments. The insulating film 254B may be similar to the insulating film 54 described previously for FIG. 5, and may be similar to the insulating film 254A. The routing 252C may be formed using techniques similar to those used to form the routing 252B. In some embodiments, additional layers of insulating film and routing may be formed by repeating these process steps.

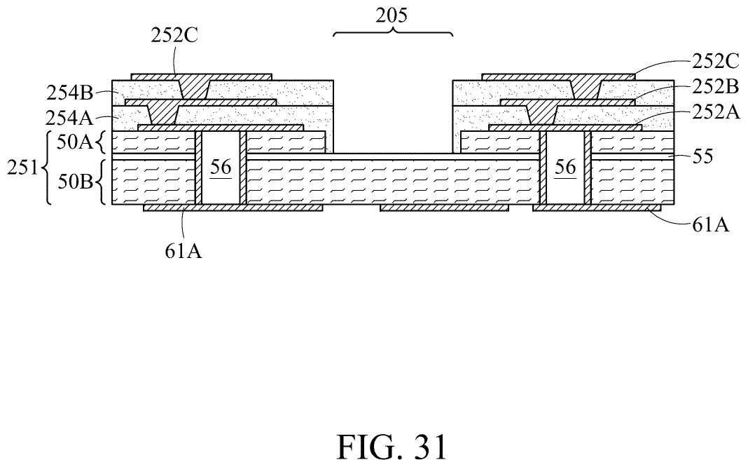

In FIG. 31, a cavity 205 is formed in the insulating films 254A-B, in accordance with some embodiments. The cavity 205 may extend fully through the insulating films 254A-B. The cavity 205 is formed over the location of the previously formed cavity 203 (see FIG. 25), and thus the cavity 205 may extend through the first core substrate 50A to expose surfaces of the adhesive layer 55 and/or the second core substrate 50B. In some embodiments, a width of the cavity 205 is less than a width of the cavity 203, such that sidewalls of the first core substrate 50A remain covered by the insulating film 254A. Additionally, some portions of the adhesive layer 55 may remain covered by the insulating film 254A. In some embodiments, a width of the cavity 205 may be between about 2 mm and about 6 mm smaller than a width of the previously formed cavity 203. Other widths are possible. The cavity 205 may be formed using a laser drilling process or another suitable technique. In some cases, a cleaning process such as a desmear process may be performed after forming the cavity 205. In other embodiments, additional layers of insulating film and/or additional layers of routing may be formed over the insulating film 254B before forming the cavity 205. Multiple cavities 203 and cavities 205 may be formed in other embodiments.

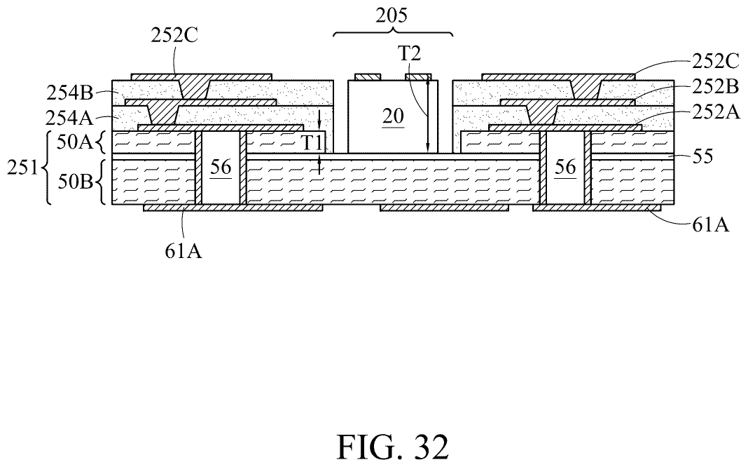

In FIG. 32, a component 20 is placed within the cavity 205, in accordance with some embodiments. The component 20 may be similar to those described previously, and may be attached to a bottom surface of the cavity 205 (e.g., a surface of the adhesive layer 55). In some embodiments, the component 20 is attached using an adhesive (not separately illustrated). In some embodiments, a width of the component 20 is less than a width of the cavity 205 such that a gap surrounds the component 20 and sidewalls of the component 20 are separated from the insulating films 254A-B. In some embodiments, a lateral distance of the gap between a sidewall of the cavity 205 (e.g., a sidewall of the insulating films 254A-B) and a sidewall of the component 20 is in the range of about 10 μm to about 50 μm. Other distances are possible. In some embodiments, the component 20 has a thickness T2 that is greater than a thickness T1 of the first core substrate 50A. Accordingly, a top surface of the component 20 protrudes above a top surface of the first core substrate 50A. In some embodiments, the thickness T2 of the component 20 is approximately the same as a depth of the cavity 205, but the thickness T2 may be greater or smaller than the depth of the cavity 205 in some cases. In some embodiments, the number and/or thicknesses of the insulating films (e.g., insulating films 254A-B) over the first core substrate 50A is chosen to correspond to a thickness T2 of the component 20. For example, in some embodiments, a top surface of the component 20 may be approximately level with a top surface of the top-most insulating film (e.g., the insulating film 254B) and/or the top-most routing (e.g., the routing 252C). In some embodiments, the component 20 has a thickness T2 in the range of about 50 μm to about 650 μm, though other thicknesses are possible. In other embodiments, multiple components 20 may be placed in one or more cavities 205.

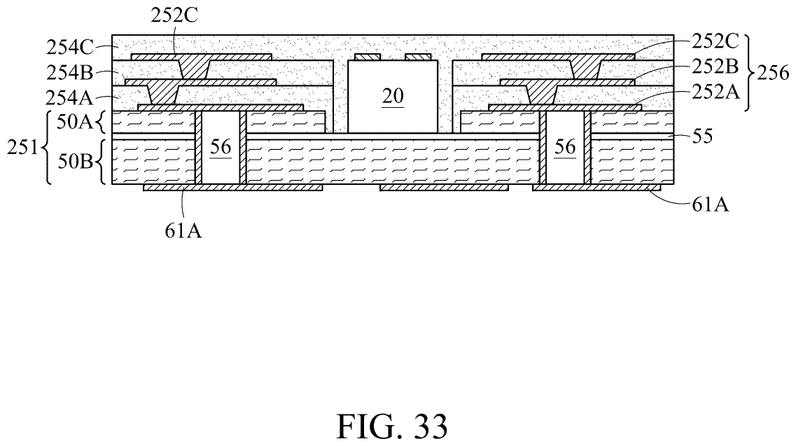

In FIG. 33, an insulating film 254C is formed over the insulating film 245B, over the routing 252C, over the component 20, and within the cavity 205. The insulating film 254C may be similar to the insulating films 254A-B. For example, in some embodiments, the insulating film 254C comprises ABF, but other materials are possible. The insulating film 254C fills the cavity 205 and covers the component 20. Accordingly, the insulating film 254C may cover surfaces of the adhesive layer 55 and the sidewalls of the component 20, in some embodiments. A thickness of the insulating film 254C on sidewalls of the component 20 may be about the same as a lateral distance of the gap described above for FIG. 32. In some cases, the insulating films 254A-C and the routing 252A-C may be considered a routing structure 256. In other embodiments, the routing structure 256 comprises another number of insulating films and/or layers of routing.

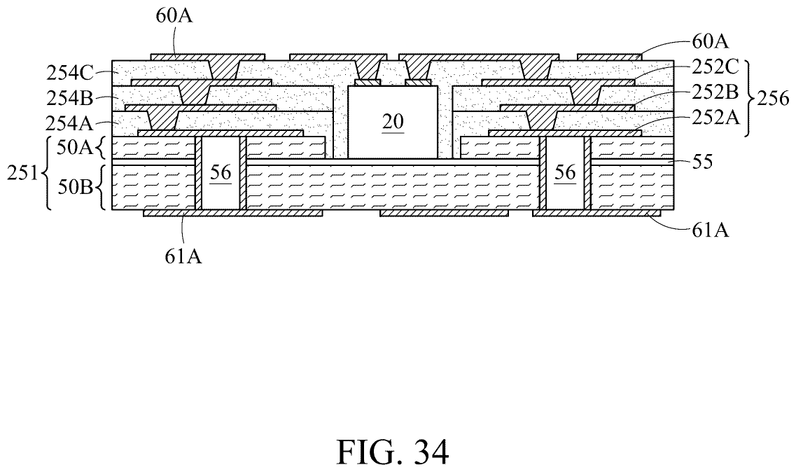

In FIG. 34, a layer of routing 60A is formed on and in the insulating film 254C, in accordance with some embodiments. The routing 60A may be formed using materials and techniques similar to that described previously for forming the routing 60A of FIG. 11. For example, openings in the insulating film 254C may be formed that expose portions of the routing 252C and the connection terminals of the component 20. A patterned mask may be formed over the insulating film 254C, and then conductive material may be deposited over the insulating film 254C and within the openings. In some embodiments, forming the routing 60A may comprise forming a conductive pre-layer over the insulating film 254C. The routing 60A may be electrically connected to the component 20 and/or the routing 252C.

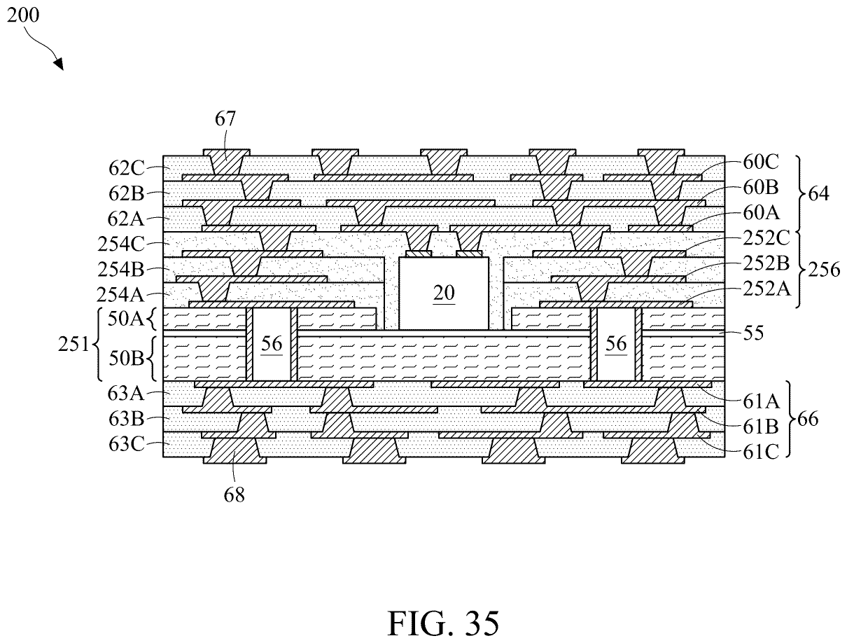

In FIG. 35, additional routing 60B-C is formed over the routing 60A to form a first routing structure 64, and additional routing 61B-C is formed over the routing 61A to form a second routing structure 66, in accordance with some embodiments. The additional routing 60B-C of the first routing structure 64 and the additional routing 61B-C of the second routing structure 66 may be formed using similar materials and techniques as described previously for FIGS. 12-13. For example, the first routing structure 64 may comprise multiple build-up layers 62A-C, and the second routing structure 66 may comprise multiple build-up layers 63A-C. The build-up layers 62A-C/63A-C may comprise materials similar or different than the insulating films 254A-C. The first routing structure 64 may comprise conductive pads 67, and the second routing structure 66 may comprise conductive pads 68. The conductive pads 67/68 may be formed using materials or techniques described previously for FIG. 13. The routing structures 64/66 may comprise another number of build-up layers and/or routing than shown.

In this manner, a package substrate structure 200 may be formed, in accordance with some embodiments. Additional process steps may be performed, such as attaching a package component (e.g., package component 80 of FIGS. 14-15) to conductive pads or forming conductive connectors on conductive pads. The techniques described herein allow for a smaller distance between the component 20 and an overlying attached package component 80 (not separately illustrated). Reducing this distance can reduce a voltage drop between the component 20 and the package component 80, which can improve the power integrity, efficiency, and performance of the package. Forming a component 20 within a multi-stack core substrate 251 as described herein can also reduce package size, improve design flexibility, improve package functionality, improve package efficiency, and improve package performance.

FIGS. 36 through 41 illustrate cross-sectional views of intermediate steps in the formation of a package substrate structure 201, in accordance with some embodiments. The package substrate structure 201 is similar to the package substrate structure 200 of FIG. 35, except that the cavity 203 is not formed. Instead, a cavity 215 is formed through the insulating layers 254A-B and the first core substrate 50A in a single process. Some materials, techniques, and/or process steps used to form the package substrate structure 201 may be similar to those used to form the package substrate structure 200, and accordingly some details may not be repeated below.

FIG. 36 illustrates a multi-stack core substrate 251′, in accordance with some embodiments. The multi-stack core substrate 251′ is similar to the multi-stack core substrate 251 of FIG. 28, except that a cavity 203 has not been formed in the first core substrate 50A. Similar to the multi-stack core substrate 251 of FIG. 28, routing 252A, routing 61A, and through vias 56 have been formed on and in the multi-stack core substrate 251′.

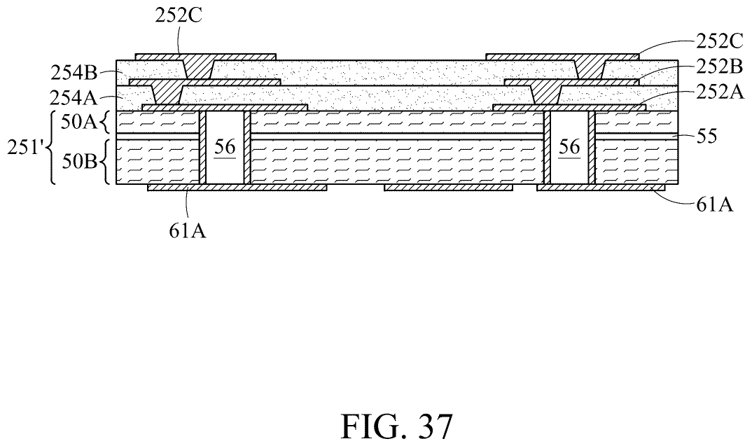

In FIG. 37, layers of routing 252A-B are formed over the first core substrate 50A, in accordance with some embodiments. The routing 252A-B may be formed using similar techniques as described for the routing 252A-B in FIGS. 29-30. For example, the routing 252A-B may be formed in and on layers of insulating film 254A-B, which may be similar to the insulating film 254A-B of FIGS. 29-30. Another number of layers of insulating film and/or routing may be formed in other embodiments.

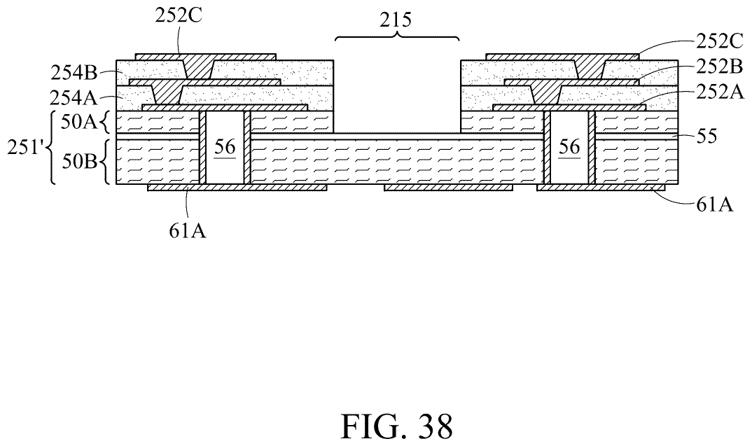

In FIG. 38, a cavity 215 is formed in the insulating films 254A-B and the first core substrate 50A, in accordance with some embodiments. The cavity 215 may extend fully through the insulating films 254A-B and the first core substrate 50A. The cavity 215 may expose surfaces of the adhesive layer 55 and/or the second core substrate 50B. In some embodiments, sidewalls of the first core substrate 50A may be exposed by the cavity 215. The cavity 215 may be formed using a laser drilling process or another suitable technique. In some cases, a cleaning process such as a desmear process may be performed after forming the cavity 215.

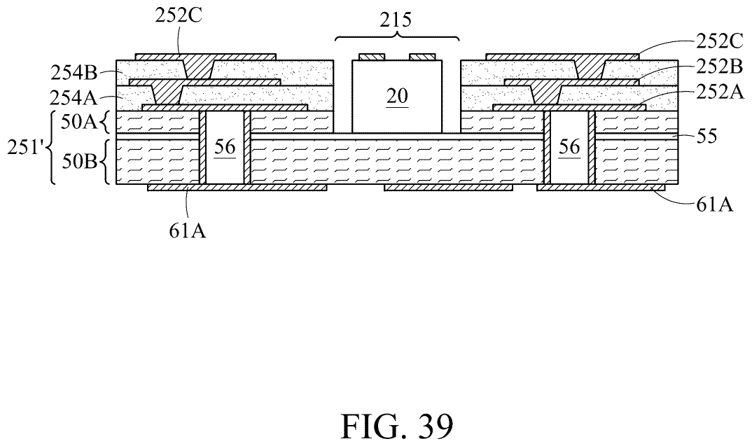

In FIG. 39, a component 20 is placed within the cavity 215, in accordance with some embodiments. The component 20 may be similar to the component 20 described previously for FIG. 32, and may be attached to a bottom surface of the cavity 215 (e.g., a surface of the adhesive layer 55). In some embodiments, the component 20 is attached using an adhesive (not separately illustrated). In some embodiments, a width of the component 20 is less than a width of the cavity 215 such that a gap surrounds the component 20 and sidewalls of the component 20 are separated from the insulating films 254A-B and the first core substrate 50A. In some embodiments, a lateral distance of the gap between a sidewall of the cavity 205 (e.g., a sidewall of the insulating films 254A-B or first core substrate 50A) and a sidewall of the component 20 is in the range of about 10 μm to about 50 μm. Other distances are possible.

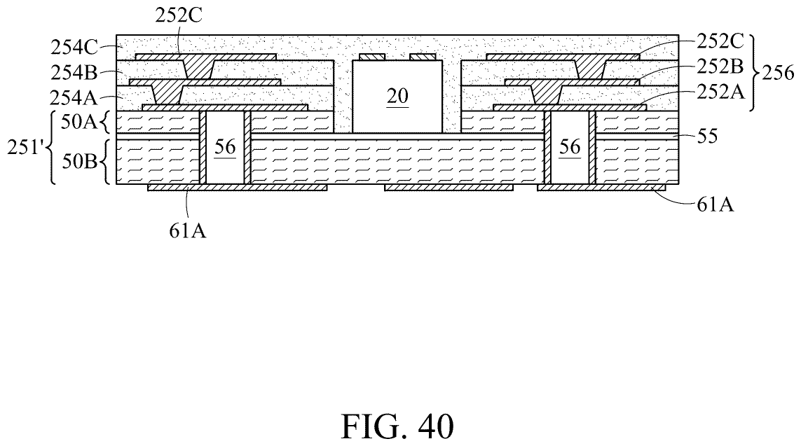

In FIG. 40, an insulating film 254C is formed over the insulating film 245B, over the routing 252C, over the component 20, and within the cavity 215. The insulating film 254C may be similar to the insulating film 254C described previously for FIG. 33. The insulating film 254C fills the cavity 215 and covers the component 20. Accordingly, the insulating film 254C may cover surfaces of the adhesive layer 55 and the sidewalls of the component 20, the sidewalls of the insulating films 254A-B, and the sidewalls of the first core substrate 50A, in some embodiments. A thickness of the insulating film 254C on sidewalls of the component 20 may be about the same as a lateral distance of the gap described above for FIG. 39. In some cases, the insulating films 254A-C and the routing 252A-C may be considered a routing structure 256. In other embodiments, the routing structure 256 comprises another number of insulating films and/or layers of routing.

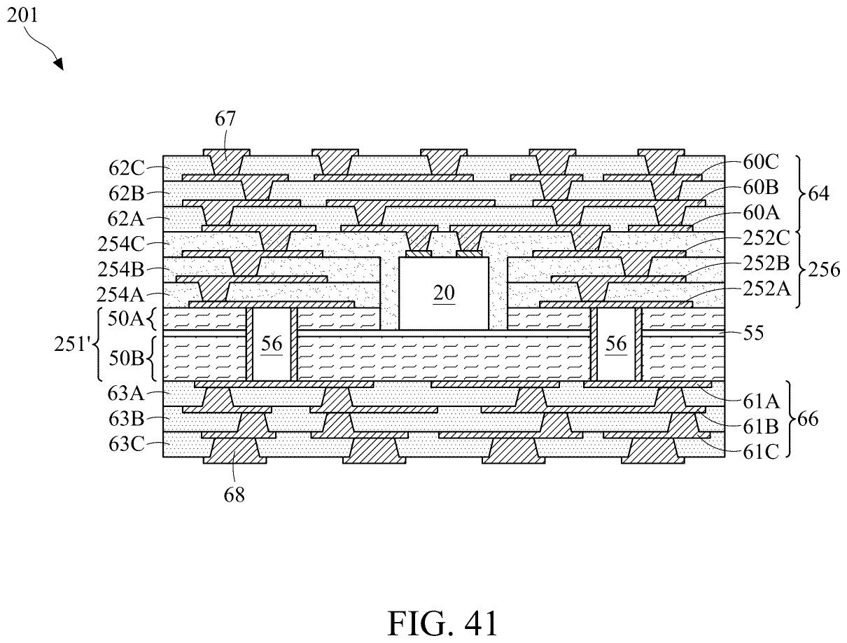

In FIG. 41, a routing structure 64 and a routing structure 66 are formed, in accordance with some embodiments. The routing structures 64/66 may be formed using techniques similar to those described previously for FIGS. 34-35. The routing structures 64/66 may comprise another number of build-up layers and/or layers of routing in other embodiments. In this manner, a package substrate structure 201 may be formed. The package substrate structure 201 has benefits similar to those described previously for the package substrate structure 200.

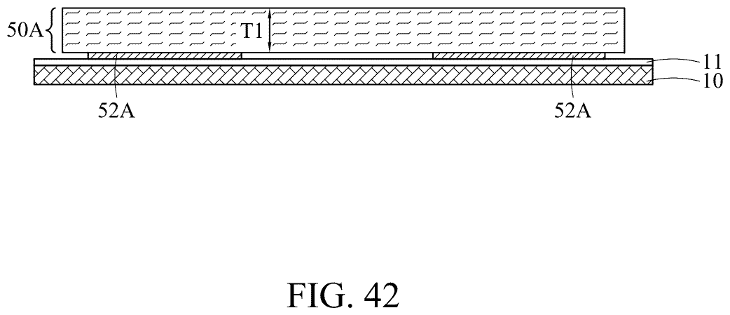

FIGS. 42 through 51 illustrate cross-sectional views of intermediate steps in the formation of a package substrate structure 300, in accordance with some embodiments. The package substrate structure 300 is similar to the package substrate structure 70 of FIG. 13, except that a thickness of the component 20 is smaller than a thickness of the first core substrate 50A. Some materials, techniques, and/or process steps used to form the package substrate structure 300 may be similar to those used to form the package substrate structure 70, and accordingly some details may not be repeated below.

FIG. 42 illustrates a first core substrate 50A attached to a first carrier 10, in accordance with some embodiments. The first core substrate 50A may be similar to the first core substrate 50A described previously for FIG. 1, and may be attached to the first carrier 10 by a release layer 11 or the like. In some embodiments, a layer of routing 52A may be formed on the bottom side of the first core substrate 50A, such as the side attached to the release layer 11. In other embodiments, the routing 52A may be formed at a subsequent process step. The routing 52A may be similar to the routing 52 described previously for FIG. 2, and may be formed using similar techniques. In some embodiments, the first core substrate 50A may have a thickness T1 that is in the range of about 50 μm to about 1200 μm, though other thicknesses are possible.

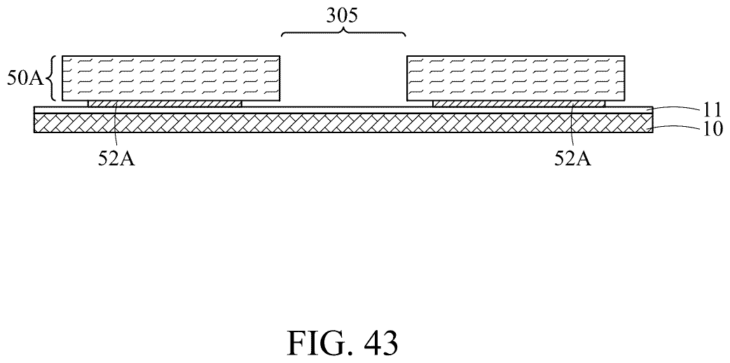

In FIG. 43, a cavity 305 is formed in the first core substrate 50A, in accordance with some embodiments. The cavity 305 may be formed using techniques similar to those described for forming the cavity 53 in FIG. 3. For example, the cavity 305 may be formed using a laser drilling process or the like. In some embodiments, a desmear process or other cleaning process may be performed after forming the cavity 305. The cavity 305 may extend completely through the first core substrate 50A, as shown in FIG. 43.

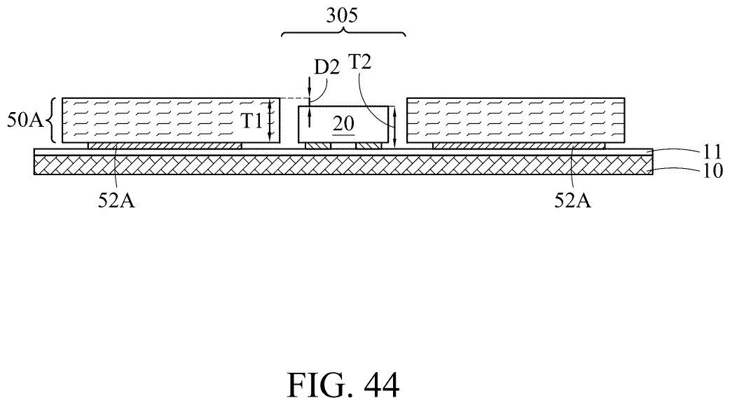

In FIG. 44, a component 20 is placed within the cavity 305, in accordance with some embodiments. The component 20 may be attached to a bottom surface of the cavity 305 (e.g., a surface of the release layer 11). In some embodiments, the component 20 is attached using an adhesive (not separately illustrated). In some embodiments, a width of the component 20 is less than a width of the cavity 305 such that a gap surrounds the component 20 and sidewalls of the component 20 are separated from the first core substrate 50A. In some embodiments, the component 20 has a thickness T2 in the range of about 40 μm to about 600 μm, though other thicknesses are possible. In some embodiments, the thickness T2 of the component 20 is less than the thickness T1 of the first core substrate 50A, such that a top surface of the first core substrate 50A is a distance D2 above a top surface of the component 20. The distance D2 may be in the range of about 10 μm to about 1200 μm, though other distances are possible.

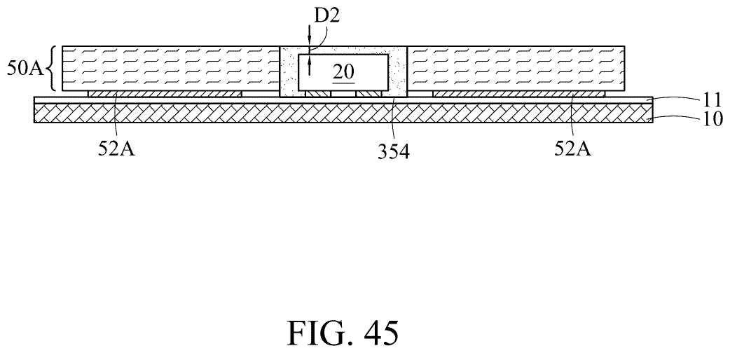

In FIG. 45, an insulating film 354 is formed over the component 20 and in the cavity 305, in accordance with some embodiments. The insulating film 354 may be similar to the insulating film 54 described previously for FIG. 5. For example, in some embodiments, the insulating film 354 comprises ABF, but other materials are possible. The insulating film 354 fills the cavity 205 and may cover surfaces of the release layer 11, in some embodiments. In some embodiments, excess insulating film 354 may be removed from top surfaces of the first core substrate 50A using a chemical mechanical polish (CMP) process, a grinding process, or the like. In some embodiments, top surfaces of the first core substrate 50A and the insulating film 354 may be approximately level or coplanar. Accordingly, a thickness of the insulating film 354 over the component 20 may be about equal to the distance D2.

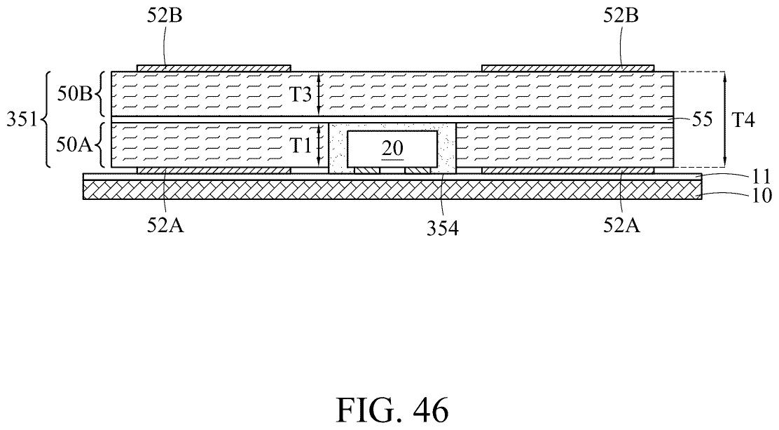

In FIG. 46, a second core substrate 50B is attached to the first core substrate 50A, in accordance with some embodiments. The second core substrate 50B may be attached to the first core substrate 50A and the insulating film 354 using an adhesive layer 55 or the like. The second core substrate 50B may be similar to the first core substrate 50A, except that the second core substrate 50B has a thickness T3 that is larger than a thickness T1 of the first core substrate 50A. The first core substrate 50A attached to the second core substrate 50B forms a multi-stack core substrate 351, in accordance with some embodiments. In some embodiments, a thickness T4 of the multi-stack core substrate 351 may be about 1200 μm or greater in order to maintain suitable rigidity and structural support. Accordingly, the thickness T3 of the second core substrate 50B may be chosen to correspond appropriately to the thickness T1 of the first core substrate 50A to provide a suitable thickness T4 for the multi-stack core substrate 351. In some embodiments, the second core substrate 50B may have a thickness T3 that is in the range of about 50 μm to about 1200 μm. Other thicknesses are possible. As shown in FIG. 46, the component 20 is surrounded by the insulating film 354 and is separated from the first core substrate 50A, the adhesive layer 55, and the second core substrate 50B by the insulating film 354. In other words, the component 20 does not physically contact the multi-stack core substrate 351.

After bonding the first core substrate 50A to the second core substrate 50B, routing 52B may be formed on the second core substrate 50B, in some embodiments. The routing 52B may be formed on the side of the second core substrate 50B opposite the first core substrate 50A. In other embodiments, the routing 52B may be formed before attachment of the second core substrate 50B or may be formed at a subsequent process step. The routing 52B may be similar to the routing 52 described previously for FIG. 2, and may be formed using similar techniques.

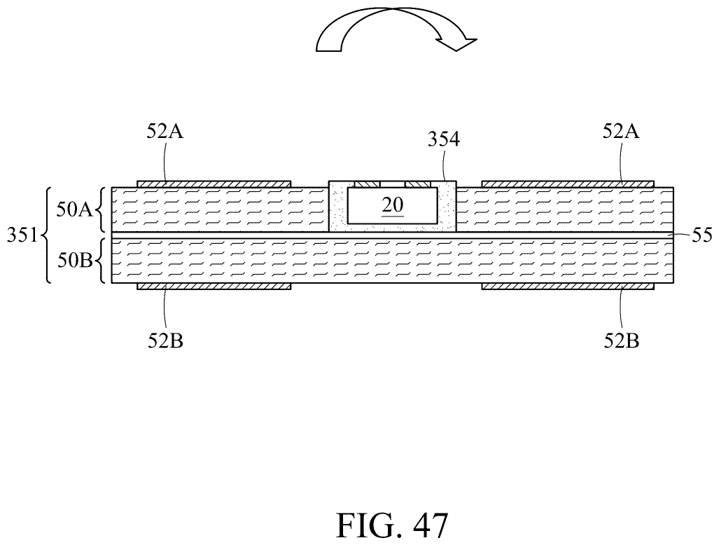

FIG. 47 illustrates the structure after debonding from the first carrier 10 and flipped over, in accordance with some embodiments. In some embodiments, the adhesive used to attach the component 20 may be removed after debonding, which may expose the connection terminals of the component 20. In some embodiments, the surface of the insulating film 354 may protrude above a surface of the first core substrate 50A, as shown in FIG. 47. In other embodiments, surfaces of the insulating film 354 and the first core substrate 50A may be approximately level or coplanar. In some embodiments, the routing 52A-B may be formed after debonding from the first carrier 10 rather than at earlier process steps as illustrated.

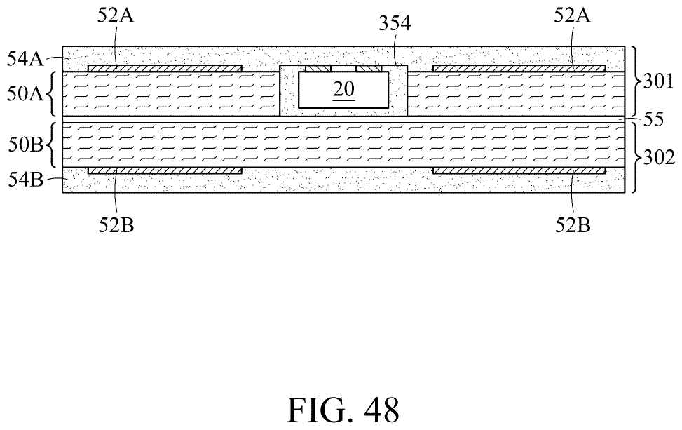

In FIG. 48, an insulating film 54A is formed over the first core substrate 50A, and an insulating film 54B is formed over the second core substrate 50B, in accordance with some embodiments. The insulating films 54A-B may be similar to the insulating film 354, in some embodiments. After forming the insulating film 54A, the component 20 is completely surrounded and isolated by the insulating film 354 and the insulating film 54A, in some embodiments. In some cases, the first core substrate 50A, component 20, insulating film 354, insulating film 54A, and routing 52A may be considered a first core structure 301, and the second core substrate 50B, insulating film 54B, and routing 52B may be considered a second core structure 302. Accordingly, the structure of FIG. 48 comprises the first core structure 301 bonded to the second core structure 302 by an adhesive layer 55.

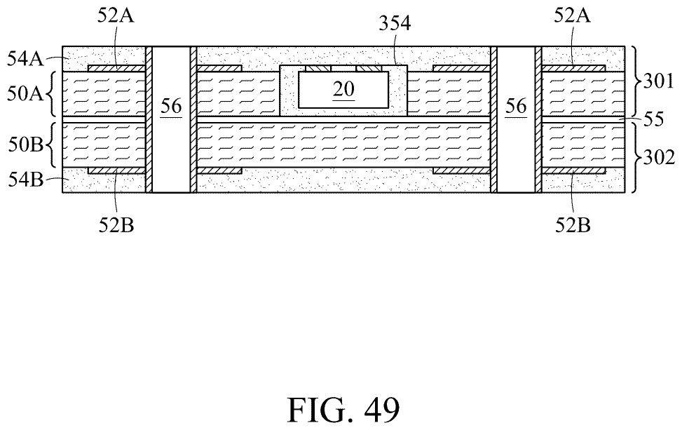

In FIG. 49, one or more through vias 56 are formed extending through the structure, in accordance with some embodiments. The through vias 56 may be similar to those described previously for FIG. 9, and may be formed using similar techniques. For example, an opening extending through the structure may be formed, and then a conductive material may be deposited within the opening to form a through via 56. The opening may then be filled with a dielectric material. In some cases, the through vias 56 may physically and electrically connect to the routing 52A and/or 52B.

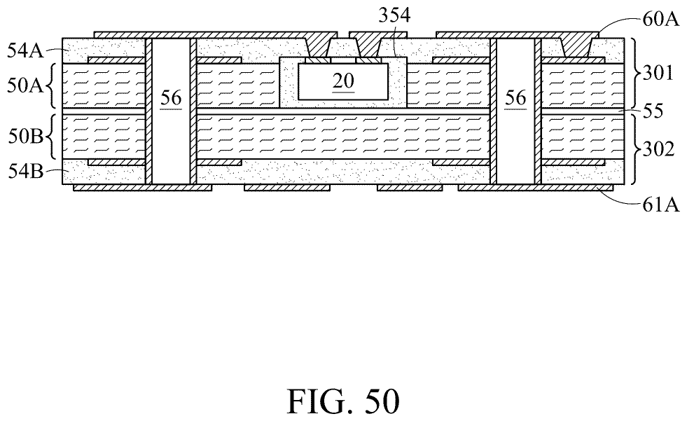

In FIG. 50, routing 60A is formed on and in the insulating film 54A, and routing 61A is formed on the insulating film 54B, in accordance with some embodiments. The routing 60A and the routing 61A may be formed using techniques similar to those described for the routing 60A of FIG. 11. The routing 60A may be electrically connected to the component 20 and to through vias 56, and the routing 61A may be electrically connected to through vias 56.

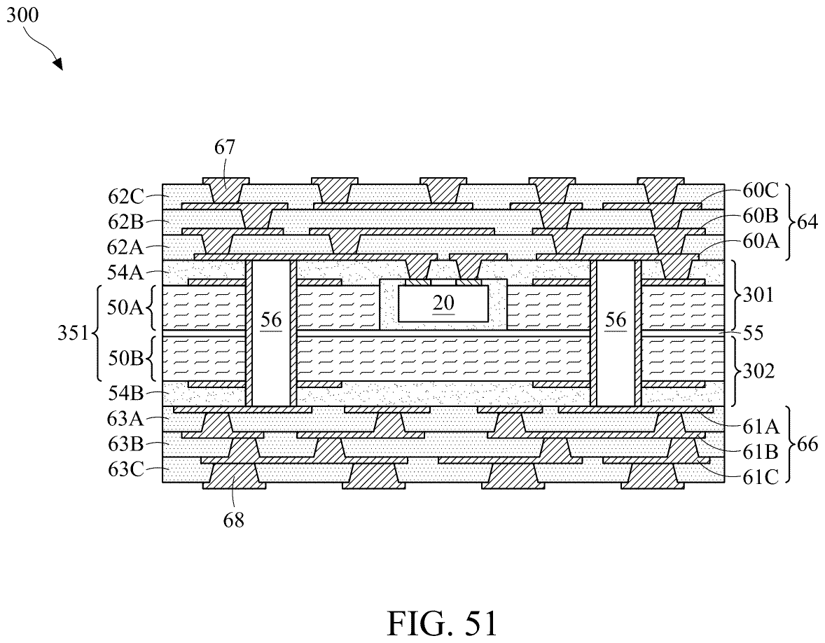

In FIG. 51, additional routing 60B-C is formed over the routing 60A to form a first routing structure 64, and additional routing 61B-C is formed over the routing 61A to form a second routing structure 66, in accordance with some embodiments. The additional routing 60B-C of the first routing structure 64 and the additional routing 61B-C of the second routing structure 66 may be formed using similar materials and techniques as described previously for FIGS. 12-13. For example, the first routing structure 64 may comprise multiple build-up layers 62A-C, and the second routing structure 66 may comprise multiple build-up layers 63A-C. The build-up layers 62A-C/63A-C may comprise materials similar or different than the insulating films 54A-B. The first routing structure 64 may comprise conductive pads 67, and the second routing structure 66 may comprise conductive pads 68. The conductive pads 67/68 may be formed using materials or techniques described previously for FIG. 13. The routing structures 64/66 may comprise another number of build-up layers and/or routing than shown.

In this manner, a package substrate structure 300 may be formed, in accordance with some embodiments. Additional process steps may be performed, such as attaching a package component (e.g., package component 80 of FIGS. 14-15) to conductive pads or forming conductive connectors on conductive pads. The techniques described herein allow for a smaller distance between the component 20 and an overlying attached package component 80 (not separately illustrated). Reducing this distance can reduce a voltage drop between the component 20 and the package component 80, which can improve the power integrity, efficiency, and performance of the package. Forming a component 20 within a multi-stack core substrate 351 as described herein can also reduce package size, improve design flexibility, improve package functionality, improve package efficiency, and improve package performance. Additionally, the multi-stack core substrate 351 as described herein may be suitable for incorporating relatively thin components 20, such as components 20 having a thickness (e.g., a thickness T2) of about 50 μm or less. Other thicknesses are possible.

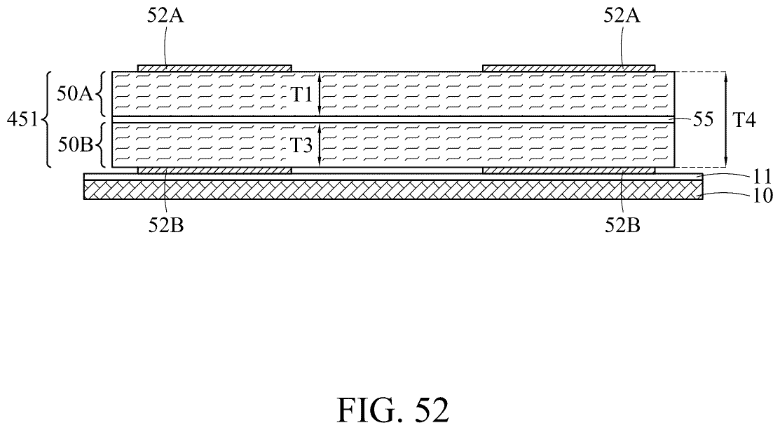

FIGS. 52 through 59 illustrate cross-sectional views of intermediate steps in the formation of a package substrate structure 400, in accordance with some embodiments. The package substrate structure 400 is similar to the package substrate structure 300 of FIG. 51, except that a cavity is formed extending completely through the multi-stack core substrate. Some materials, techniques, and/or process steps used to form the package substrate structure 500 may be similar to those used to form the package substrate structure 300 and/or the package substrate structure 70, and accordingly some details may not be repeated below.

FIG. 52 illustrates a multi-stack core substrate 451 comprising a first core substrate 50A attached to a second core substrate 50B, in accordance with some embodiments. The second core substrate 50B may be attached to the first core substrate 50A using an adhesive layer 55 or the like. In some embodiments, the first core substrate 50A may have a thickness T1 that is in the range of about 50 μm to about 650 μm, and the second core substrate 50B may have a thickness T3 that is in the range of about 50 μm to about 650 μm. Other thicknesses are possible. In some embodiments, a thickness T4 of the multi-stack core substrate 451 may be about 1200 μm or greater in order to maintain suitable rigidity and structural support. Accordingly, the thicknesses T1 and T3 of the core substrates 50A-B may be chosen such that the thickness T4 is greater than about 1200 μm, in some embodiments. Other thicknesses are possible. In some embodiments, routing 52A-B may be formed on the core substrates 50A-B, in some embodiments. The routing 52A may be formed on the first core substrate 50A, and the routing 52B may be formed on the second core substrate 50B. In other embodiments, the routing 52A-B may be formed before attachment of the core substrates 50A-B. The routing 52A-B may be similar to the routing 52 described previously for FIG. 2, and may be formed using similar techniques. FIG. 52 shows the multi-stack core substrate 451 attached to a first carrier 10 by a release layer 11, such that the second core substrate 50B is adjacent the first carrier 10.

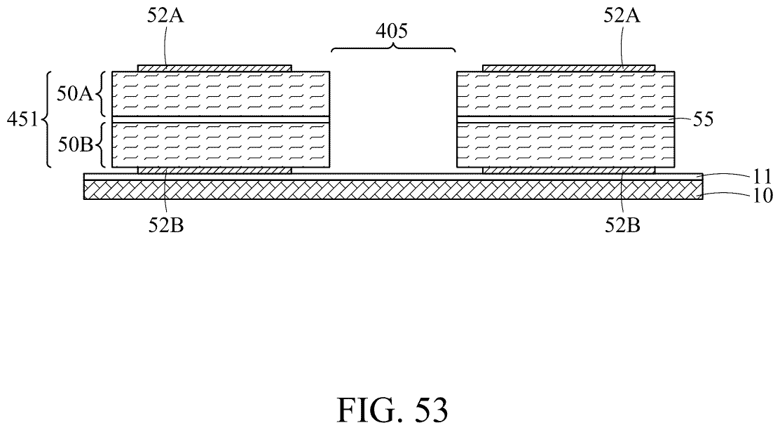

In FIG. 53, a cavity 405 is formed in the multi-stack core substrate 451, in accordance with some embodiments. The cavity 405 may be formed using techniques similar to those described for forming the cavity 53 in FIG. 3. For example, the cavity 405 may be formed using a laser drilling process, a mechanical drilling process, or the like. In some embodiments, a desmear process or other cleaning process may be performed after forming the cavity 405. The cavity 405 may extend completely through the multi-stack core substrate 451, as shown in FIG. 53.

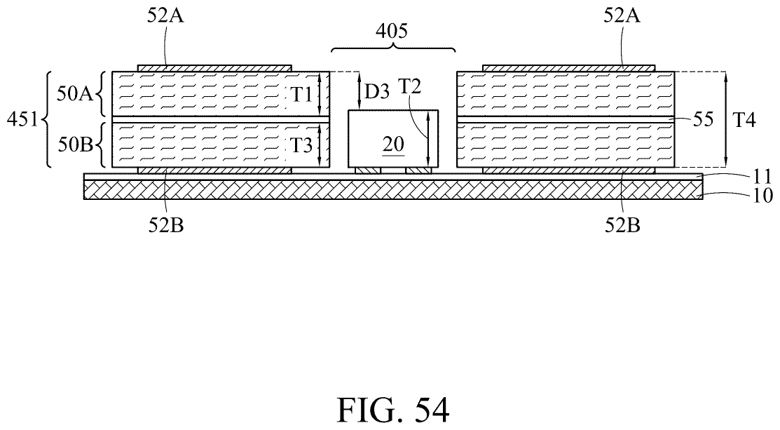

In FIG. 54, a component 20 is placed within the cavity 405, in accordance with some embodiments. The component 20 may be attached to a bottom surface of the cavity 405 (e.g., a surface of the release layer 11). In some embodiments, the component 20 is attached using an adhesive (not separately illustrated). In some embodiments, a width of the component 20 is less than a width of the cavity 405 such that a gap surrounds the component 20 and sidewalls of the component 20 are separated from the multi-stack core substrate 451. In some embodiments, the component 20 has a thickness T2 in the range of about 50 μm to about 1200 μm, though other thicknesses are possible. For example, in some embodiments, the component 20 may be a relatively thick stacked device, system on integrated circuit (SoIC), or the like comprising two or more dies that are bonded together (e.g., using direct bonding, hybrid bonding, fusion bonding, conductive connectors, or the like). In some embodiments, the thickness T2 of the component 20 may be greater than, less than, or about the same as the thickness T3 of the second core substrate 50B. Accordingly, a distance D3 between a top surface of the first core substrate 50A and a top surface of the component 20 may be greater than, less than, or about the same as the thickness T1 of the first core substrate 50A. The distance D3 may be in the range of about 10 μm to about 1200 μm, though other distances are possible.

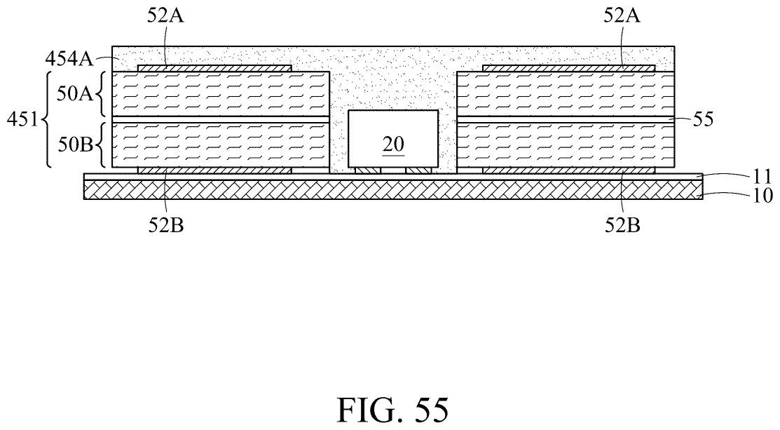

In FIG. 55, an insulating film 454A is formed over the multi-stack core substrate 451, over the component 20, and within the cavity 405. The insulating film 454A may be similar to the insulating film 54 described previously for FIG. 5. For example, in some embodiments, the insulating film 454A comprises ABF, but other materials are possible. The insulating film 454A fills the cavity 405 and covers the component 20. The insulating film 454A may cover the first core substrate 50A, surfaces of the release layer 11, sidewalls of the component 20, and sidewalls of the multi-stack core substrate 451, in some embodiments. In this manner, the component 20 may be separated from the multi-stack core substrate 451 by the insulating film 454A.

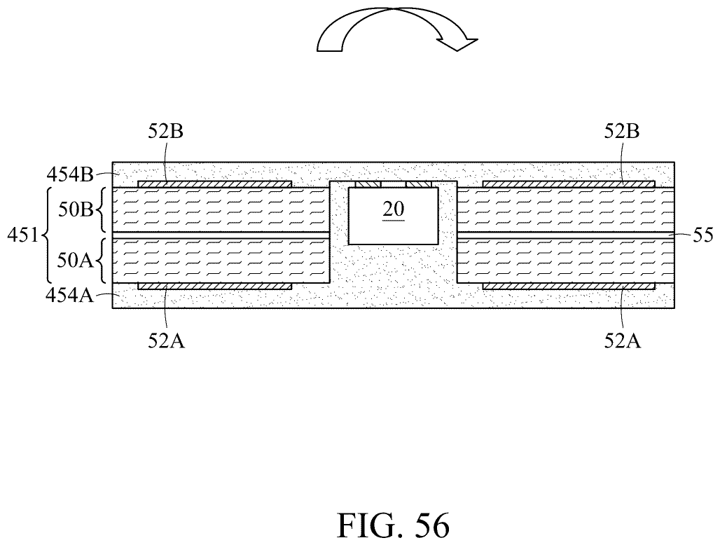

In FIG. 56, the multi-stack core substrate 451 is debonded from the first carrier 10 and flipped over, and an insulating film 454B is formed over the second core substrate 50B, in accordance with some embodiments. The insulating film 454B may be similar to the insulating 454A, in some embodiments. After forming the insulating film 454B, the component 20 is completely surrounded and isolated by the insulating films 454A-B, in some embodiments. In some embodiments, the surface of the insulating film 454A may protrude above a surface of the second core substrate 50B, as shown in FIG. 56. In other embodiments, surfaces of the insulating film 454A and the second core substrate 50B may be approximately level or coplanar.

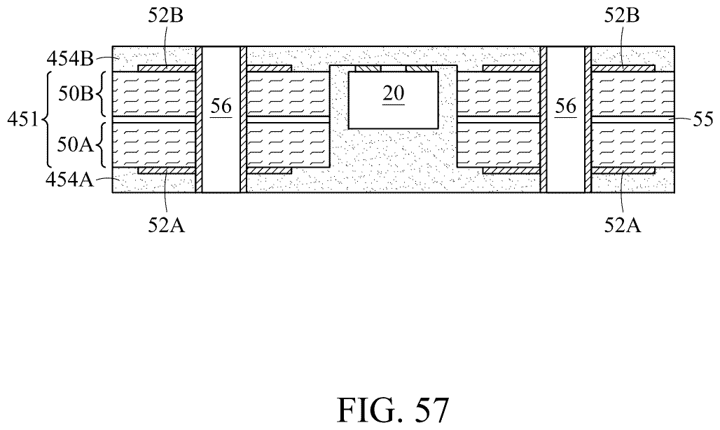

In FIG. 57, one or more through vias 56 are formed extending through the structure, in accordance with some embodiments. The through vias 56 may be similar to those described previously for FIG. 9, and may be formed using similar techniques. For example, an opening extending through the structure may be formed, and then a conductive material may be deposited within the opening to form a through via 56. The opening may then be filled with a dielectric material. In some cases, the through vias 56 may physically and electrically connect to the routing 52A and/or 52B.

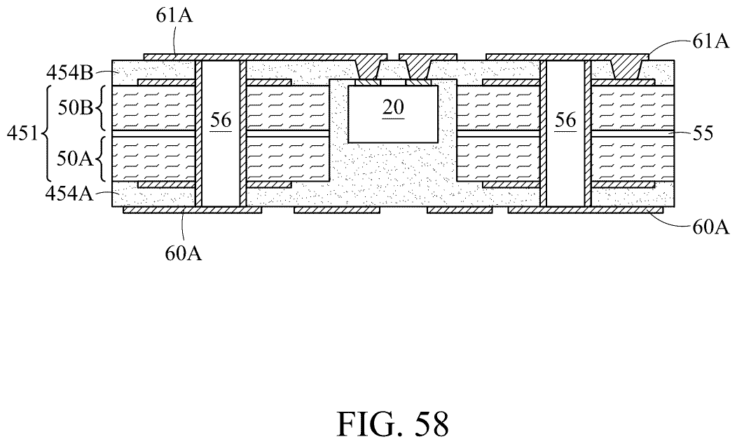

In FIG. 58, routing 60A is formed on and in the insulating film 454A, and routing 61A is formed on the insulating film 454B, in accordance with some embodiments. The routing 60A and the routing 61A may be formed using techniques similar to those described for the routing 60A of FIG. 11. The routing 61A may be electrically connected to the component 20 and to through vias 56, and the routing 60A may be electrically connected to through vias 56.

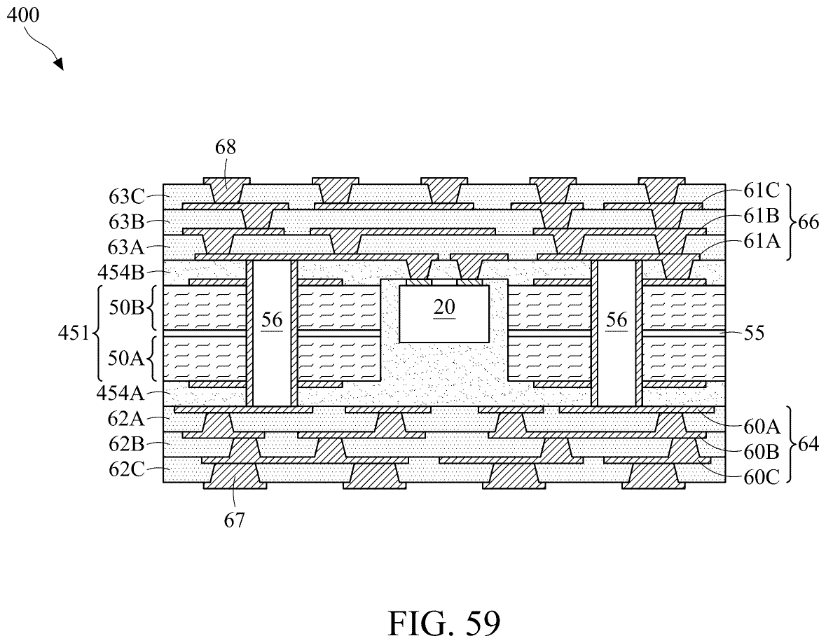

In FIG. 59, additional routing 60B-C is formed over the routing 60A to form a first routing structure 64, and additional routing 61B-C is formed over the routing 61A to form a second routing structure 66, in accordance with some embodiments. The additional routing 60B-C of the first routing structure 64 and the additional routing 61B-C of the second routing structure 66 may be formed using similar materials and techniques as described previously for FIGS. 12-13. For example, the first routing structure 64 may comprise multiple build-up layers 62A-C, and the second routing structure 66 may comprise multiple build-up layers 63A-C. The build-up layers 62A-C/63A-C may comprise materials similar or different than the insulating films 454A-B. The first routing structure 64 may comprise conductive pads 67, and the second routing structure 66 may comprise conductive pads 68. The conductive pads 67/68 may be formed using materials or techniques described previously for FIG. 13. The routing structures 64/66 may comprise another number of build-up layers and/or routing than shown.

In this manner, a package substrate structure 400 may be formed, in accordance with some embodiments. Additional process steps may be performed, such as attaching a package component (e.g., package component 80 of FIGS. 14-15) to conductive pads or forming conductive connectors on conductive pads. The techniques described herein allow for a smaller distance between the component 20 and an overlying attached package component 80 (not separately illustrated). Reducing this distance can reduce a voltage drop between the component 20 and the package component 80, which can improve the power integrity, efficiency, and performance of the package. Forming a component 20 within a multi-stack core substrate 451 as described herein can also reduce package size, improve design flexibility, improve package functionality, improve package efficiency, and improve package performance. Additionally, the multi-stack core substrate 451 as described herein may be suitable for incorporating relatively thin components 20 or relatively thick components 20, such as components 20 having a thickness (e.g., a thickness T2) less than about 50 μm or greater than about 600 μm. Other thicknesses are possible.

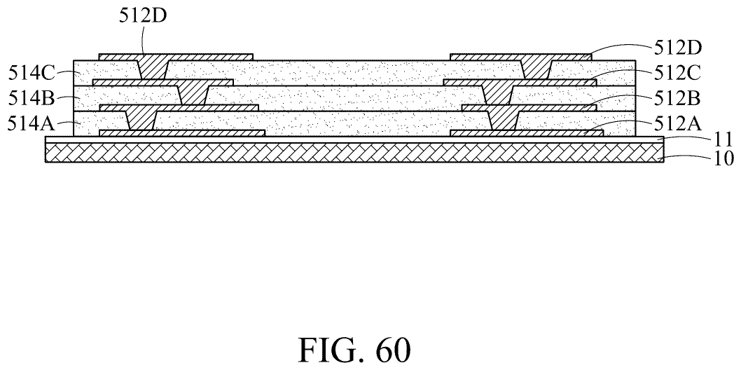

FIGS. 60 through 67 illustrate cross-sectional views of intermediate steps in the formation of a package substrate structure 500, in accordance with some embodiments. The package substrate structure 500 is similar to package substrate structures described previously, except that package substrate structure 500 is formed by forming routing structures separately and then bonding them to a core structure. The routing structures and the core structure may each include one or more components (e.g., active or passive devices), in some embodiments. Some materials, techniques, and/or process steps used to form the package substrate structure 500 may be similar to those used to form other package substrate structures described herein, and accordingly some details may not be repeated below.

FIGS. 60 through 64 illustrate intermediate steps in the formation of a first routing structure 510, in accordance with some embodiments. In FIG. 60, multiple layers of routing 512A-D are formed over a first carrier 10, in accordance with some embodiments. In some embodiments, a release layer 11 is also present on the first carrier 10. The routing 512A-D may be formed using techniques similar to those described for forming the routing structure 256, such as those described for FIGS. 28-30. For example, routing 512A may be formed over the release layer 11 using techniques similar to those used for forming the routing 252A. An insulating film 514A may be formed over the routing 512A and the release layer 11, which may be similar to the insulating film 254A or the like. In some embodiments, the insulating film 514A comprises ABF, but other materials, such as a build-up layer, are possible. Openings may be formed in the insulating film 514 using a laser drilling process or the like, and then conductive material may be deposited on and in the insulating film 514A using a patterned mask. Similar steps may be repeated to form a plurality of layers of routing 512A-D on and in a plurality of layers of insulating film 514A-C. Another number of layers of insulating film and/or routing may be formed in other embodiments. In other embodiments, the routing layers may be formed on and in build-up layers, similar to the formation of the routing structure 66 of FIG. 13.

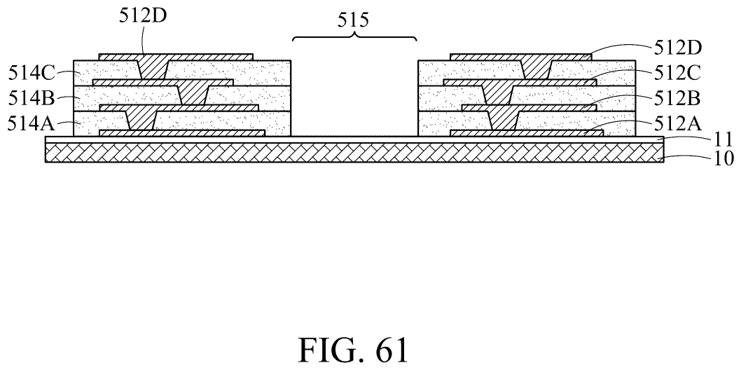

In FIG. 61, a cavity 515 is formed in the insulating films 514A-C, in accordance with some embodiments. The cavity 515 may extend fully through the insulating films 514A-C. The cavity 515 may expose surfaces of the release layer 11. The cavity 515 may be formed using a laser drilling process or another suitable technique. In some cases, a cleaning process such as a desmear process may be performed after forming the cavity 515.

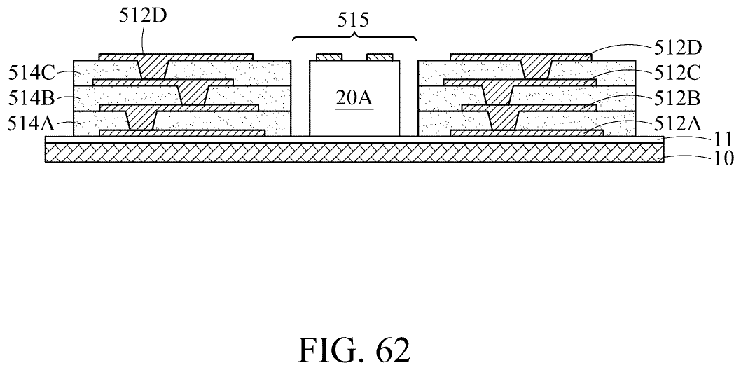

In FIG. 62, a component 20A is placed within the cavity 515, in accordance with some embodiments. The component 20A may be similar to components 20 described previously, and may be attached to a bottom surface of the cavity 515 (e.g., a surface of the release layer 11). In some embodiments, the component 20A is attached using an adhesive (not separately illustrated). In some embodiments, a width of the component 20A is less than a width of the cavity 515 such that a gap surrounds the component 20A. In some embodiments, a thickness of the component 20A is approximately the same as a depth of the cavity 515, though other thicknesses are possible. Multiple components 20A may be used in other embodiments.

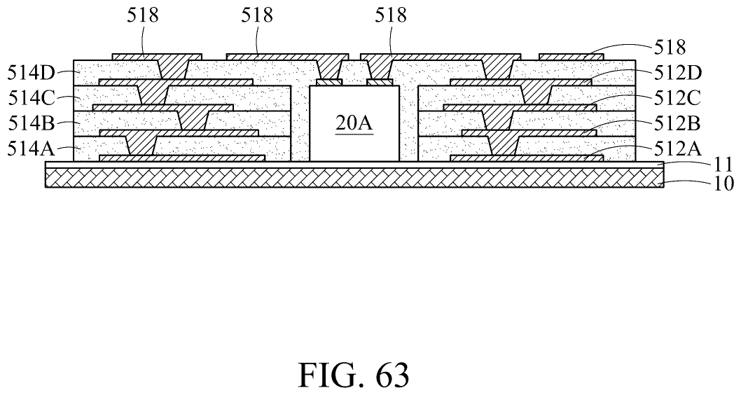

In FIG. 63, an insulating film 514D is formed over the insulating film 514C, over the component 20A, and within the cavity 515. The material of the insulating film 514D may be similar to or different from the insulating films 514A-C. For example, in some embodiments, the insulating film 514D comprises ABF, but other materials are possible. The insulating film 514D fills the cavity 515 and covers the component 20A. Accordingly, the insulating film 514D may cover surfaces of the release layer 11 and the sidewalls of the component 20A. Further in FIG. 63, a layer of routing 518 is formed on and in the insulating film 514D, in accordance with some embodiments. The routing 518 may be formed using materials and techniques similar to that described previously for forming the routing 60A of FIG. 34. The routing 518 may be electrically connected to the component 20A and/or the routing 512D.

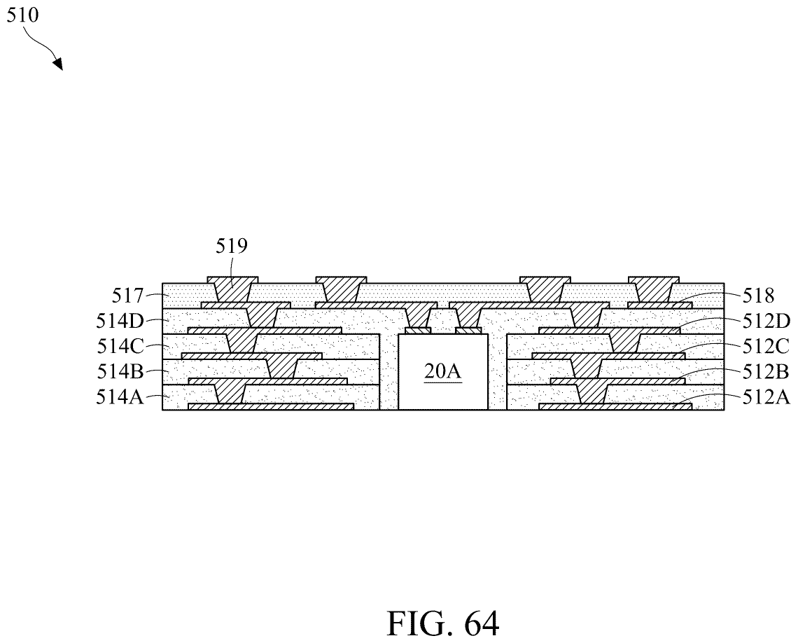

In FIG. 64, conductive pads 519 are formed over the insulating film 514D to form the first routing structure 510, in accordance with some embodiments. The conductive pads 519 may be formed using techniques similar to those described for forming the conductive pads 67 of FIG. 13. For example, a build-up layer 517 may be formed over the insulating film 514D and the routing 518. Openings may be formed in the build-up layer 517 using a laser drilling process or the like, and then conductive material may be deposited on and in the build-up layer 517 using a patterned mask. Additional layers of build-up layers and/or routing may be formed in other embodiments. In other embodiments, the conductive pads 519 may be formed on and in an insulating film, similar to the formation of the routing structure 66 of FIG. 13. While the first routing structure 510 is shown having four layers of insulating film 514A-D and one build-up layer 517, all of these layers may be the same material (e.g., ABF, build-up material, or the like) or may have a different arrangement of various layers of different materials.

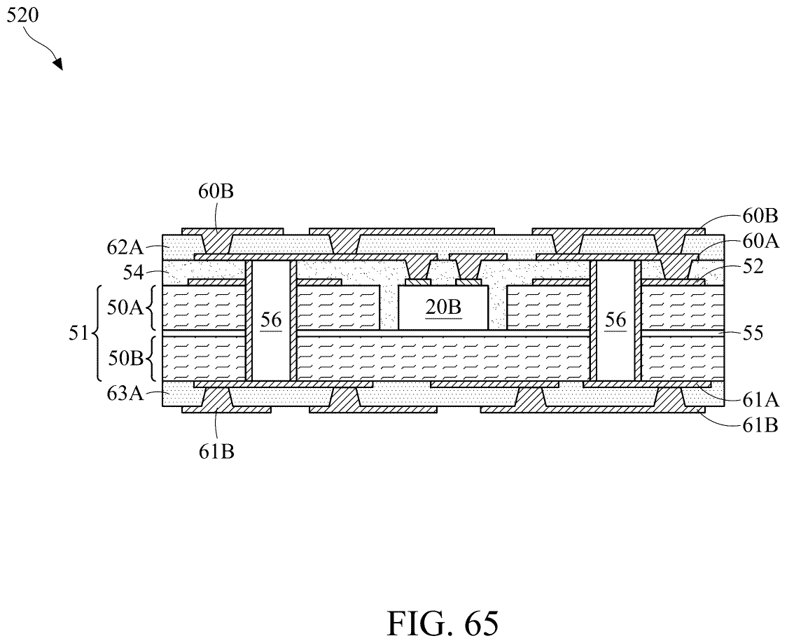

FIG. 65 illustrates a core structure 520, in accordance with some embodiments. The core structure 520 is similar to the structure shown in FIG. 12, and may be formed using similar techniques. For example, the core structure 520 may comprise a multi-stack core substrate 51 formed of a first core substrate 50A bonded to a second core substrate 50B. It should be noted that the core structure 520 shown in FIG. 65 is an example, and the core structure 520 may be similar to other core structures, other multi-stack core substrates, or other package substrate structures described herein. In some embodiments, the multi-stack core substrate 51 has a thickness of about 1200 μm or greater, though other thicknesses are possible. For reference, the side of the core structure 520 over the first core substrate 50A (e.g., the side facing upward in FIG. 65) may be referred to as the “top side,” and the side of the core structure 520 over the second core substrate 50B (e.g., the side facing downward in FIG. 65) may be referred to as the “bottom side.” A cavity may be formed in the first core substrate 50A, and a component 20B disposed within the cavity. An insulating film 54 covers the first core substrate 50A and the component 20A and also fills the cavity. Routing 60A-B is formed over the first core substrate 50A, with a build-up layer 62A being between the routing 60A and the routing 60B. Routing 61A-B is formed over the second core substrate 50B, with a build-up layer 63A being between the routing 61A and the routing 61B. Additional build-up layers and layers of routing may be formed on the structure in other embodiments. In some cases, the routing 60A-B with the build-up layer 62A may be considered a routing structure, and the routing 61A-B with the build-up layer 63A may be considered a routing structure.

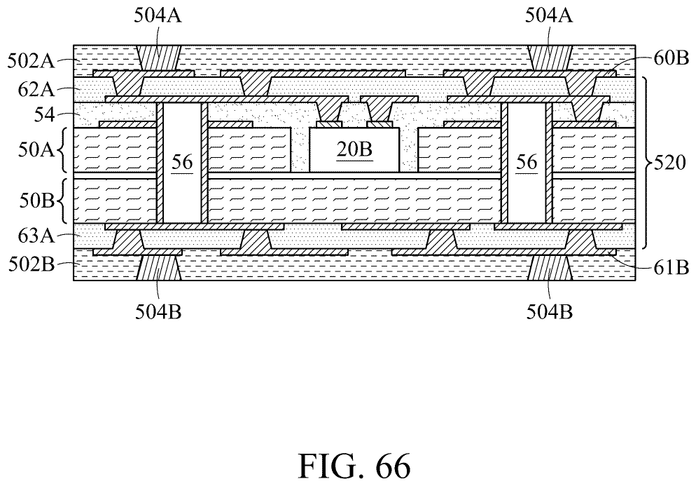

In FIG. 66, a first bonding film 502A is formed over the top side of the core structure 520 and a second bonding film 502B is formed over the bottom side of the core structure 520, in accordance with some embodiments. In an embodiment, the bonding films 502A-B may be a pre-impregnated composite fiber (prepreg) material, a polymer resin film, an epoxy resin film, an adhesive film, a dielectric material, or the like. In some embodiments, the bonding films 502A-B may be applied to the core structure 520 using a process such as a spin-on coating process, a dip coating method, an air-knife coating method, a curtain coating method, a wire-bar coating method, a gravure coating method, a lamination method, an extrusion coating method, a combination of these, or the like. In an embodiment, the bonding films 502A-B may be applied in liquid or semi-liquid form and then subsequently cured or partially cured. However, any suitable material and method of formation may be utilized.

In some embodiments, via regions 504A are formed extending through the first bonding film 502A, and via regions 504B are formed extending through the second bonding film 502B. The via regions 504A are conductive regions that physically and electrically connect to the routing 60B, and the via regions 504B are conductive regions that physically and electrically connect to the routing 61B. The via regions 504A may be formed, for example, by forming openings in the first bonding film 502A and then depositing conductive material in the openings. The via regions 504B may be formed, for example, by forming openings in the second bonding film 502B and then depositing conductive material in the openings. The conductive material of the via regions 504A and the via regions 504B may be deposited simultaneously, in some cases. In other embodiments, the via regions 504A-B may be formed on the core structure 520 prior to forming the bonding films 502A-B. In some embodiments, top surfaces of the via regions 504A and the first bonding film 502A are substantially coplanar or level, and top surfaces of the via regions 504B and the second bonding film 502B are substantially coplanar or level.

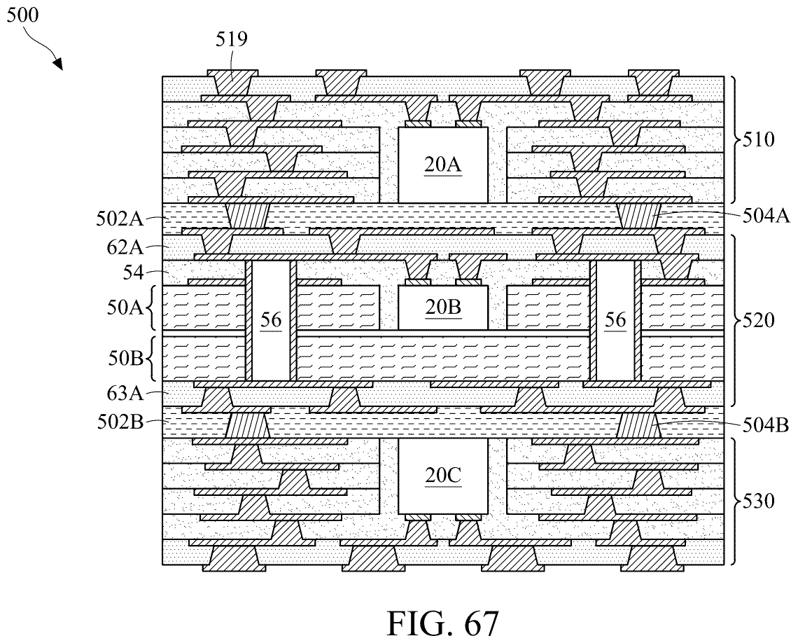

In FIG. 67, the first routing structure 510 is attached to the core structure 520 by the first bonding film 502A and a second routing structure 530 is attached to the core structure 520 by the second bonding film 502B, in accordance with some embodiments. In this manner, the package substrate structure 500 may be formed, in accordance with some embodiments. The second routing structure 530 may be similar to the first routing structure 510, and may be formed using similar materials or techniques. For example, the second routing structure 530 may include a component 20C within various routing layers. The first routing structure 510 and the second routing structure 530 may have different numbers of routing layers, in some cases. The first routing structure 510 is electrically connected to the core structure 520 by the via regions 504A, and the second routing structure 530 is electrically connected to the core structure 520 by the via regions 504B.

The first routing structure 510 may be placed on the first bonding film 502A, with routing 512A contacting the via regions 504A. In some embodiments, an adhesive layer (not separately illustrated) may be formed between the first bonding film 502A and the first routing structure 510 to facilitate attachment. Similarly, the second routing structure 530 may be placed on the second bonding film 502B. An adhesive layer (not illustrated) may be present between the second bonding film 502B and the second routing structure 530. The bonding films 502A-B may then be cured in order to harden the material of the bonding films 502A-B. In some embodiments, the structure may also be pressed to facilitate attachment of the routing structures 510/530 to the core structure 520. This is an example, and other attachment techniques are possible. In other embodiments, additional core structures and/or routing structures may be attached using bonding film. In other embodiments, only one of the first routing structure 510 or the second routing structure 530 is present.

In this manner, a package substrate structure 500 may be formed, in accordance with some embodiments. Additional process steps may be performed, such as attaching a package component (e.g., package component 80 of FIGS. 14-15) to conductive pads or forming conductive connectors on conductive pads. The techniques described herein allow for a smaller distance between components and external structures, such as a package component 80. Additionally, techniques described herein allow for the formation of a package substrate structure comprising multiple components, which can reduce package size, improve design flexibility, improve package functionality, improve package efficiency, and improve package performance.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. Techniques described herein allow for the formation of a package substrate that incorporates one or more components (e.g., active or passive devices) embedded within, while also allowing the package substrate to have sufficient rigidity and thickness. Some of the package substrates described herein comprise core substrates attached together into a single multi-stack core substrate. In some embodiments, metal features, conductive routing, ground planes, power planes, or the like are not present between the attached core substrates. In this manner, the multi-stack core substrates described herein can embed a thin component and efficiently form electrical connections to the component. The multi-stack core substrates described herein can reduce warping of a package. The package substrate structures described herein can be incorporated into a wide variety of packages, such as Integrated Fan-Out (InFO) packages, Chip-on-Wafer-on-Substrate (CoWoS) packages, or other suitable packages. In some cases, the techniques described herein can allow for reduced cost, reduced package size, improved design flexibility, improved package stability, and improved power integrity.

In some embodiments, a structure includes a first core substrate; an adhesive layer on the first core substrate; a second core substrate on the adhesive layer, wherein the second core substrate includes a first cavity; a first semiconductor device within the first cavity; a first insulating film extending over the second core substrate, over a top surface of the first semiconductor device, and within the first cavity; a through via extending through the first insulating film, the first core substrate, and the second core substrate; a first routing structure on the first core substrate and electrically connected to the through via; and a second routing structure on the first insulating film and electrically connected to the through via and the first semiconductor device. In an embodiment, the structure includes a second cavity within the first core substrate; a second semiconductor device within the second cavity; and a second insulating film extending over the first core substrate, over the second semiconductor device, and within the second cavity. In an embodiment, a thickness of the first semiconductor device is greater than a thickness of the second core substrate. In an embodiment, a thickness of the first core substrate is different from a thickness of the second core substrate. In an embodiment, the first insulating film covers a bottom surface of the first semiconductor device. In an embodiment, the structure includes a package component bonded to the second routing structure. In an embodiment, the first insulating film physically contacts the adhesive layer. In an embodiment, the first semiconductor device is separated from the second core substrate by the first insulating film.

In some embodiments, a package includes a multi-stack core substrate including a first core substrate bonded to a second core substrate by an adhesive layer; a first layer of insulating film within the first core substrate and laterally surrounded by the first core substrate; a first component within the first layer of insulating film and laterally surrounded by the first layer of insulating film; and a through via extending through the multi-stack core substrate. In an embodiment, the first component is fully separated from the multi-stack core substrate by the first layer of insulating film. In an embodiment, top surfaces of the first core substrate are free of the first layer of insulating film. In an embodiment, the first layer of insulating film is within the second core substrate and is laterally surrounded by the second core substrate. In an embodiment, a total thickness of the multi-stack core substrate is at least 1200 μm. In an embodiment, the package includes a second layer of insulating film over top surfaces of the first core substrate, the first layer of insulating film, and the first component. In an embodiment, the insulating film includes Ajinomoto build-up film (ABF). In an embodiment, a thickness of the first component is smaller than a thickness of the first core substrate.

In some embodiments, a method includes forming a cavity extending through a first core substrate; placing a die within the cavity, wherein die is separated from the first core substrate; forming an insulating film over the first core substrate and the die, wherein the insulating film fills the cavity; forming a first adhesive material on the first core substrate and the die; bonding a second core substrate to the first adhesive material; forming a through via extending through the insulating film, the first core substrate, the first adhesive material, and the second core substrate; forming a first routing layer on the insulating film and the die; and forming a second routing layer on the second core substrate. In an embodiment, the method includes forming a second adhesive material on the first routing layer; and bonding a first routing structure to the second adhesive material. In an embodiment, the second adhesive material includes a layer of pre-impregnated composite fiber (prepreg) material. In an embodiment, the method includes forming a third adhesive material on the second routing layer; and bonding a second routing structure to the third adhesive material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a first core substrate;
an adhesive layer on the first core substrate;
a second core substrate on the adhesive layer, wherein the second core substrate comprises a first cavity;
a first semiconductor device within the first cavity;
a first insulating film extending over the second core substrate, over a top surface of the first semiconductor device, and within the first cavity;
a through via extending through the first insulating film, the first core substrate, and the second core substrate;
a first routing structure on the first core substrate and electrically connected to the through via; and
a second routing structure on the first insulating film and electrically connected to the through via and the first semiconductor device.

2. The structure of claim 1 further comprising:
a second cavity within the first core substrate;
a second semiconductor device within the second cavity; and
a second insulating film extending over the first core substrate, over the second semiconductor device, and within the second cavity.

3. The structure of claim 1, wherein a thickness of the first semiconductor device is greater than a thickness of the second core substrate.

4. The structure of claim 1, wherein a thickness of the first core substrate is different from a thickness of the second core substrate.

5. The structure of claim 1, wherein the first insulating film covers a bottom surface of the first semiconductor device.

6. The structure of claim 1 further comprising a package component bonded to the second routing structure.

7. The structure of claim 1, wherein the first insulating film physically contacts the adhesive layer.

8. The structure of claim 1, wherein the first semiconductor device is separated from the second core substrate by the first insulating film.

9. A package comprising:
a multi-stack core substrate comprising a first core substrate bonded to a second core substrate by an adhesive layer;
a first layer of insulating film within the first core substrate and laterally surrounded by the first core substrate;
a first component within the first layer of insulating film and laterally surrounded by the first layer of insulating film; and
a through via extending through the multi-stack core substrate.

10. The package of claim 9, wherein the first component is fully separated from the multi-stack core substrate by the first layer of insulating film.

11. The package of claim 9, wherein top surfaces of the first core substrate are free of the first layer of insulating film.

12. The package of claim 9, wherein the first layer of insulating film is within the second core substrate and is laterally surrounded by the second core substrate.

13. The package of claim 9, wherein a total thickness of the multi-stack core substrate is at least 1200 μm.

14. The package of claim 9 further comprising a second layer of insulating film over top surfaces of the first core substrate, the first layer of insulating film, and the first component.

15. The package of claim 9, wherein the insulating film comprises Ajinomoto build-up film (ABF).

16. The package of claim 9, wherein a thickness of the first component is smaller than a thickness of the first core substrate.

17. A method comprising:
forming a cavity extending through a first core substrate;
placing a die within the cavity, wherein die is separated from the first core substrate;
forming an insulating film over the first core substrate and the die, wherein the insulating film fills the cavity;
forming a first adhesive material on the first core substrate and the die;
bonding a second core substrate to the first adhesive material;
forming a through via extending through the insulating film, the first core substrate, the first adhesive material, and the second core substrate;
forming a first routing layer on the insulating film and the die; and
forming a second routing layer on the second core substrate.

18. The method of claim 17 further comprising:
forming a second adhesive material on the first routing layer; and
bonding a first routing structure to the second adhesive material.

19. The method of claim 18, wherein the second adhesive material comprises a layer of pre-impregnated composite fiber (prepreg) material.

20. The method of claim 17 further comprising:
forming a third adhesive material on the second routing layer; and
bonding a second routing structure to the third adhesive material.
